(19) United States
(12) Patent Application Publication
(10) Pub. No.: US 2026/0190348 A1
(43) Pub. Date: Jul. 2, 2026

(54) HIGH-TEMPERATURE FERROELECTRIC MEMORY DEVICES

(71) Applicant: THE TRUSTEES OF THE UNIVERSITY OF PENNSYLVANIA, Philadelphia, PA (US)

(72) Inventors: Kim GWANGWOO, Chungcheongbuk-do (KR); Deep JARIWALA, Philadelphia, PA (US); Roy Harold OLSSON, III, Phoenixville, PA (US); Dhiren K. PRADHAN, Philadelphia, PA (US); Yunfei HE, Philadelphia, PA (US); Shangyi CHEN, Santa Clara, CA (US); Kwan-Ho KIM, Philadelphia, PA (US); Zirun HAN, Arcadia, CA (US); Yinuo ZHANG, Philadelphia, PA (US)

(21) Appl. No.: 19/544,363

(22) Filed: Feb. 19, 2026

Related U.S. Application Data
(63) Continuation-in-part of application No. PCT/US2024/043290, filed on Aug. 21, 2024.
(60) Provisional application No. 63/520,812, filed on Aug. 21, 2023.
(60) Provisional application No. 63/601,920, filed on Nov. 22, 2023.

(51) Int. Cl. H10B 53/30

(52) U.S. Cl. CPC H10B 53/30

(57) ABSTRACT

A ferroelectric non-volatile memory component, comprising: a first electrode comprising a first metal; a ferroelectric portion; and a second electrode comprising a second metal; the ferroelectric portion placing the first electrode and the second electrode into electronic communication with one another, the ferroelectric portion optionally contacting at least one of the first electrode and the second electrode, the ferroelectric portion comprising AlₓSc₍₁₋ₓ₎N, the component optionally comprising a non-ferroelectric interlayer disposed between the ferroelectric portion and the first electrode and/or between the ferroelectric portion and the second electrode, and the component optionally exhibiting at least one of (a) an operating voltage of less than 15 V at 600° C., (b) an on/off ratio of greater than 1 at a temperature at 600° C., and (c) retention of a polar state following exposure to 1 Mrad Cobalt-60 (⁶⁰Co) gamma radiation. A ferroelectric capacitor, comprising: a first electrode comprising a first metal; a ferroelectric portion, the ferroelectric portion comprising AlₓSc₍₁₋ₓ₎N; a second electrode comprising a second metal; and a silicon carbide portion; the ferroelectric portion contacting the first electrode and the silicon carbide portion, the second electrode contacting the silicon carbide portion. A ferroelectric component, comprising: a ferroelectric portion, the ferroelectric portion comprising AlₓSc₍₁₋ₓ₎N; a first electrode comprising a first metal, the first electrode surmounting at least a portion of the ferroelectric portion; and a second electrode comprising a second metal.

### RELATED APPLICATIONS

The present application is a continuation in part of international patent application no. PCT/US2024/043290, “High-Temperature Ferroelectric Memory Devices” (filed Aug. 21, 2024); which claims priority to and the benefit of U.S. patent application No. 63/520,812, “High-Temperature Ferroelectric Memory Devices” (filed Aug. 21, 2023) and U.S. patent application No. 63/601,920, “Scaled AlScN Ferroelectric Diodes With Optimized Performance” (filed Nov. 22, 2023). All foregoing applications are incorporated herein by reference in their entireties for any and all purposes.

### GOVERNMENT RIGHTS

This invention was made with government support under 1542153, and 1720530 awarded by the National Science Foundation, FA8650-22-D-5400, and FA9550-23-1-0391 awarded by the Air Force Office of Scientific Research, and W911NF-19-2-0119 awarded by the Army Research Laboratory—Army Research Office. The government has certain rights in the invention.

### TECHNICAL FIELD

The present disclosure relates to the field of ferroelectric devices and also relates to the field of memory devices.

### BACKGROUND

Existing silicon-based technology (including non-volatile memory technology) is useful in a broad range of applications, but such technology operates reliably at only comparatively low temperatures, thereby limiting the technology's application in demanding environments and extreme conditions. Although ferroelectric materials have been identified as having a range of applications—including memory applications, such materials have to date been formed only on substrates that do not tolerate comparatively high temperatures. Accordingly, there is a long-felt need in the art for ferroelectric devices that can operate at comparatively high temperatures.

### SUMMARY

In meeting the described long-felt needs, the present disclosure provides a ferroelectric non-volatile memory component, comprising: a first electrode comprising a first metal; a ferroelectric portion; and a second electrode comprising a second metal; the ferroelectric portion placing the first electrode and the second electrode into electronic communication with one another, the ferroelectric portion optionally contacting at least one of the first electrode and the second electrode, the ferroelectric portion comprising AlₓSc₍₁₋ₓ₎N, the component optionally comprising a non-ferroelectric interlayer disposed between the ferroelectric portion and the first electrode and/or between the ferroelectric portion and the second electrode, and the component optionally exhibiting at least one of (a) an operating voltage of less than 15 V at 600° C., (b) an on/off ratio of greater than 1 at 600° C., and (c) retention of a polar state following exposure to 1 Mrad Cobalt-60 (⁶⁰Co) gamma radiation.

Also provided is a method, the method comprising operating a component according to the present disclosure.

Further provided is a method, comprising applying a voltage to a component according to the present disclosure so as to convert the component between a first persistent electronic polarization and conduction state and a second persistent electronic polarization and conduction state.

Additionally provided is a computing device, the computing device comprising a component according to the present disclosure.

Further disclosed is a ferroelectric capacitor, comprising: a first electrode comprising a first metal; a ferroelectric portion, the ferroelectric portion comprising AlₓSc₍₁₋ₓ₎N; a second electrode comprising a second metal; and a silicon carbide portion; the ferroelectric portion contacting the first electrode and the silicon carbide portion, the second electrode contacting the silicon carbide portion.

Also disclosed is a method, comprising operating a capacitor according to the present disclosure.

Further provided is a method, comprising applying a voltage to a component according to the present disclosure so as to convert the component between a first persistent electronic polarization and conduction state and a second electronic polarization and conduction persistent state.

Additionally provided is a ferroelectric component, comprising: a ferroelectric portion, the ferroelectric portion comprising AlₓSc₍₁₋ₓ₎N; a first electrode comprising a first metal, the first electrode surmounting at least a portion of the ferroelectric portion; and a second electrode comprising a second metal.

Also disclosed is a method, comprising operating a capacitor according to the present disclosure.

Further provided is a method, comprising applying a voltage to a component according to the present disclosure so as to convert the component between a first persistent electronic polarization and conduction state and a second persistent electronic polarization and conduction state.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various aspects discussed in the present document. In the drawings:

FIG. 1 (a). Schematic (b) AFM height image (c) a composite image of the AlScN device showing each layer (on the left is cross sectional TEM and on the right is a labeled schematic) (d) cross sectional TEM of the Ni/Al_{0.68}Sc_{0.32}N/Pt (111) MIM device.

FIG. 2(a) Quasi-DC current (I) versus voltage (V) at selected temperatures (b) Coercive Field versus temperature (c) On and Off current (off current is the lower value at each temperature) (d) On-Off ratio at 5 V read voltage as a function of temperature of Ni/Al_{0.68}Sc_{0.32}N/Pt (111) MIM device.

FIG. 3 (a) Pulse IV current density (J) versus electric field (E) at different temperatures (b) Pulse IV current density (J) versus time (c) Coercive field (E_{C}) vs temperature (d) PUND traces at select temperatures (e) Remnant polarization vs PUND voltage for each temperature and (f) Remnant polarization vs temperature measured at E_{C}*1.26 for relative consistency.

FIG. 4(a)>1M Retention cycles at 5 V read voltage 500° C. (b) Retention behavior at 5 V read voltage at 500° C. (c) Pulse IV survival tests during 19V write cycling at 500° C. of Ni/Al_{0.68}Sc_{0.32}N/Pt (111) MIM device. (d) Positive and negative switching voltages from test pulse IV vs number of cycles

FIG. 5: (a) DC I-V curve (b) the first derivative of current w.r.t voltage at 400° C.

FIG. 6: Exemplary C-V curve of a Ni/Al_{0.68}Sc_{0.32}N/Pt (111) MIM device measured at room temperature.

FIG. 7: Temperature dependence of Absolute current difference

FIG. 8: An exemplary PUND measurement performed on an example device according to the present disclosure; the measurement is performed at room temperature (RT).

FIG. 9: Pulsed-IV rates spanning from 1 Hz to 10 kHz

FIG. 10: Retention behavior at 5 V read voltage, at RT.

FIG. 11: Raw pulse currents for read tests demonstrating averaging scheme. Note that 25 pulses were averaged for each datapoint, but only 5 are shown for clarity.

FIG. 12: (left) Write endurance test at performed at RT. (right) comparison of peak trends in RT tests vs 500° C.

FIG. 13. (a) Schematic of the metal/Al_{0.68}Sc_{0.32}N/SiC semiconductor ferroelectric capacitor. The blue arrow in Al_{0.68}Sc_{0.32}N represents the as deposited direction of the ferroelectric dipoles, the dashed arrow in Al_{0.68}Sc_{0.32}N represents the potential direction of the ferroelectric dipoles after switching. (b) Micrograph of the fabricated MFS capacitor Al electrode with a diameter of 25 μm. (c) AFM of the 30-nm-thick Al_{0.68}Sc_{0.32}N thin film on SiC exhibits an ultra-low surface roughness of 0.2 nm. (d) Cross-sectional TEM image of the AlScN ferroelectric capacitor on the SiC substrate. (e) High-resolution TEM image of the interface between Al_{0.68}Sc_{0.32}N and the SiC substrate. (f) The diffraction pattern of the MFeS stack confirming the crystal structure and orientation.

FIG. 14. (a) I-V characteristics of a DC sweep on the ferroelectric capacitor device using a semi-log scale, with four arrows indicating the sweeping sequences. Inset: a magnified region that highlights the ferroelectric switching with an on-off ratio of 3.1 at −5 V. (b) J-E hysteresis loop under 100 kHz of the Al_{0.68}Sc_{0.32}N on SiC substrate, the arrows indicate the current peak contributed by the ferroelectric and resistive components. (c)-(f) A single asymmetric PUND measurement on a 25 μm-diameter top Al electrode with “P”, “U”, “N”, and “D” sequences presented individually, under the voltage pulse of −24/+38 V, with rise time as 100 ns and pulse width as 2 μs. The current contributed by the ferroelectric and resistive were indicated by the arrows in (c) and (e). (g)-(h) The remanent polarization (Pᵣ) of the AlScN/SiC ferroelectric capacitor, calculated from the PUND measurement under different applied voltages.

FIG. 15. (a) Retention performance of the Al_{0.68}Sc_{0.32}N/SiC ferroelectric capacitor for Up and Down directions up to 10⁶ s, using PUND/NDPU test readouts. (b) Polarization of individual pulses of “P”, “U”, “N”, and “D” as a function of cycle number during endurance testing with fatigue pulses. (c) 2Pᵣ calculated by “Up”=P-U, “Down”=N-D, with respect to cycle number, demonstrating the stability of the Al_{0.68}Sc_{0.32}N/SiC ferroelectric capacitor with an endurance of approximately 3.7×10³ cycles.

FIG. 16: I-V curve of the 220-nm-thick Ni/SiC/Ni structure showing ohmic contact between Ni and SiC interface (with the radius of the Ni-circular pad of R=25 μm) after annealing in the furnace at 1050° C. for 2 min. The furnace is under vacuum with Ar gas flowing during the annealing process.

FIG. 17. Fabrication steps of the MFeS capacitor structure: (a) Ni deposition by sputtering and patterning, (b) Ni annealing, (c) AlScN deposition by sputtering, (d) Al deposition by sputtering, (e) positive photoresist S1813 spin coating, (f) positive photoresist S1813 patterning (g) Al dry etch, (h) AlScN wet etch, (i) S1813 stripping.

FIG. 18. Electron microscopy data of the Al/Al_{0.68}Sc_{0.32}N/SiC MFeS capacitor: (a) Cross-sectional TEM image of the AlScN ferroelectric capacitor on the SiC substrate, the inset at the left top corner displays the diffraction pattern of the MFeS stack confirming the crystal structure and orientation. (b) Magnified high-resolution TEM image of the region labeled in yellow dashed square, the white dashed lines indicate the interfaces of Al/AlScN and AlScN/Ni.

FIG. 19. TCAD Sentaurus simulation results for the AlScN/SiC ferroelectric capacitor: (a) A simplified AlScN/SiC stack capacitor structure, where the pink region represents the heavily n-type doped SiC substrate and the yellow region corresponds to the AlScN layer. Voltage of 37.5 V is applied to the left edge of the SiC, while the right edge of the AlScN is grounded. The white line indicates the depletion region within the SiC substrate; (b) Voltage distribution across the entire capacitor, showcasing the voltage division by the depletion region of the SiC substrate. The voltage across the AlScN layer is 19.43 V, resulting in a corresponding electric field of 6.48 MV cm⁻¹ within the AlScN layer.

FIG. 20. Schematic of the sequence of (a) PUND/(b) NDPU measurements for retention measurement of the demonstrated MFeS capacitor. We obtained the polarization corresponding to (a) Down/(b) Up states after different set of retention times.

FIG. 21A provides a cross-sectional view of an exemplary device according to the present disclosure. As shown, the device includes a Pt electrode superposed on a Si substate (Pt/Si), with a layer of Al_{0.64}Sc_{0.36}N atop the Pt. An AlOx interlayer is disposed on the AlScN layer; in this non-limiting instance, the interlayer has a thickness of about 6 nm. Ni electrode material is disposed on the interlayer; in this non-limiting instance, the Ni electrodes are about 150 nm in thickness, though this is not a required thickness.

FIG. 21B provides example voltage v. current data for a device according to FIG. 21A across a range of temperatures. As shown, the difference in current at a given voltage is greater at lower temperatures; for example, the current difference at 5 V at 25° C. is greater than at 600° C.

FIG. 21C provides example temperature vs. current data for on and off current for a device according to FIG. 21A. As shown, there are differences between on and off currents across the range of provided temperatures.

FIG. 21D provides example temperature vs. Ec data for a device according to FIG. 21A. As shown, there are differences between the positive and negative coercive fields across the range of provided temperatures.

FIG. 21E provides example temperature vs. rectification ratio data for a device according to FIG. 21A. As shown, there are differences in the rectification ratios in the on and off states across the range of provided temperatures.

FIG. 21F provides example temperature vs. on-off ratio data for a device according to FIG. 21A.

FIG. 21G provides example E vs. J data for a device according to FIG. 21A.

FIG. 21H provides example time vs. J data for a device according to FIG. 21A.

FIG. 21I provides example temperature vs. Ec data for a device according to FIG. 21A. As shown, there are differences in the Ec values for positive and negative coercive fields across the range of provided temperatures.

FIG. 21J provides example time vs. current data for a device according to FIG. 21A.

FIG. 21K provides example voltage vs. 2P_{R} (P-U and N-D) data for a device according to FIG. 21A.

FIG. 21L provides example temperature vs. P_{R} data for a device according to FIG. 21A.

FIG. 22A provides a cross-sectional view of an exemplary device according to the present disclosure. As shown, the device includes a Pt electrode superposed on a Si substate (Pt/Si), with a layer of Al_{0.64}Sc_{0.36}N atop the Pt. An AlOx interlayer is disposed on the AlScN layer; in this non-limiting instance, the interlayer has a thickness of about 10 nm. Ni electrode material is disposed on the interlayer; in this non-limiting instance, the Ni electrodes are about 150 nm in thickness.

FIG. 22B provides example voltage v. current data for a device according to FIG. 22B across a range of temperatures. As shown, the difference in current at a given voltage is greater at lower temperatures; for example, the current difference at 5 V at 25° C. is greater than at 600° C.

FIG. 22C provides example temperature vs. current data for on and off current for a device according to FIG. 22A.

FIG. 22D provides example temperature vs. rectification ratio data for a device according to FIG. 22A.

FIG. 22E provides example temperature vs. Ec data for a device according to FIG. 22A.

FIG. 22F provides example temperature vs. on-off ratio data for a device according to FIG. 22A.

FIG. 22G provides example E vs. J data for a device according to FIG. 22A.

FIG. 22H provides example time vs. J data for a device according to FIG. 22A.

FIG. 22I provides example temperature vs. Ec data for a device according to FIG. 22A.

FIG. 22K provides example voltage vs. 2P_{R} (P-U and N-D) data for a device according to FIG. 22A.

FIG. 22K provides example temperature vs. P_{R} data for a device according to FIG. 22A.

FIG. 22L provides example time vs. current data for a device according to FIG. 22A.

FIG. 23A provides a view of an exemplary device according to the present disclosure. As shown, a layer of AlScN (for example, AlSc_{0.32}N) can be placed on a SiC substrate. Electrodes (in this instance, Ni) can be placed on the SiC substrate and on the AlScN layer.

FIG. 23B provides example roughness data for a device according to FIG. 23A.

FIG. 23C provides example room temperature data for a device according to FIG. 23A.

FIG. 23D provides example AC-IV PUND data for a device according to FIG. 23A.

FIG. 23E provides example electric field vs. current density and voltage vs. current density data for a device according to FIG. 23A at a range of temperatures.

FIG. 23F provides example electric field vs. current density and voltage vs. current density data for a device according to FIG. 23A at a range of temperatures.

FIG. 23G provides example temperature vs. coercive field data for a device according to FIG. 23A at a range of temperatures.

FIG. 23H provides example electric field vs. current density and voltage vs. current density data for a device according to FIG. 23A at a range of temperatures.

FIG. 23I provides example temperature vs. coercive field data for a device according to FIG. 23A at a range of temperatures.

FIG. 23J provides example time vs. current data for a device according to FIG. 23A at a range of temperatures.

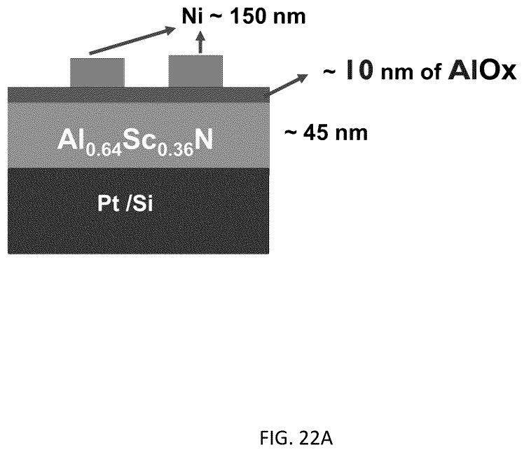

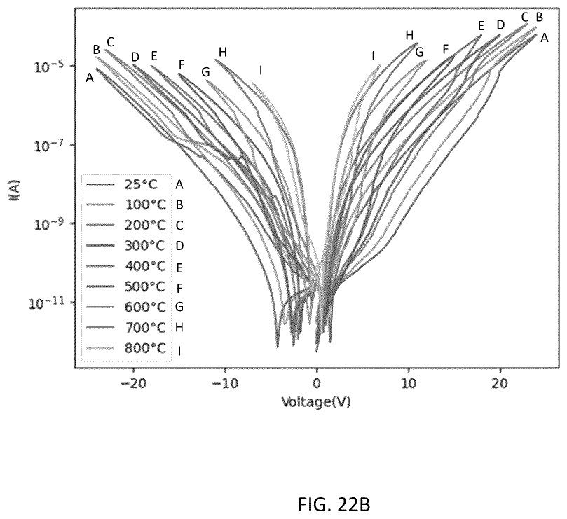

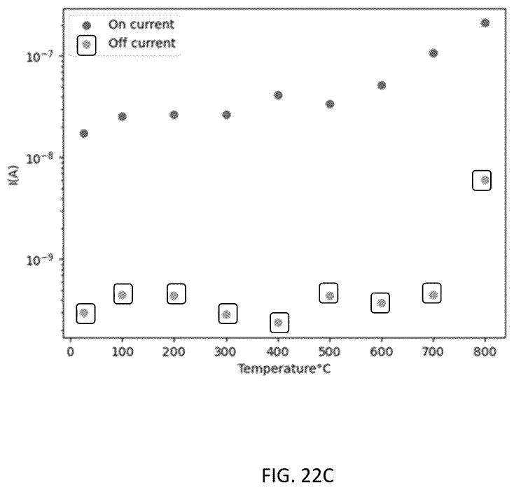

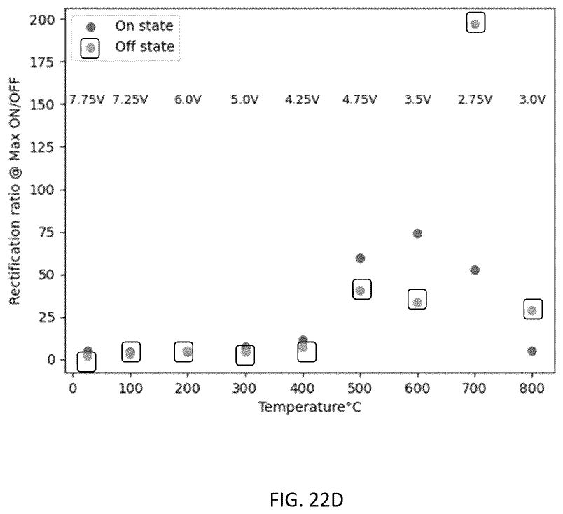

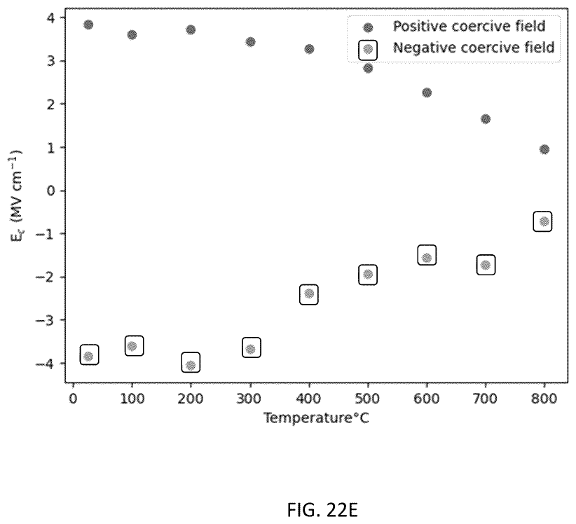

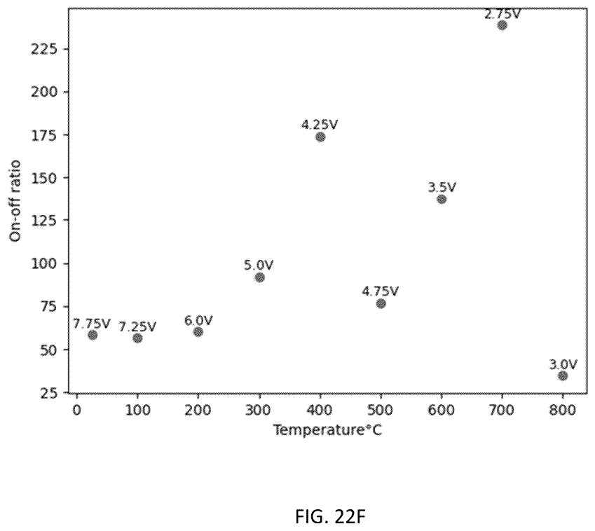

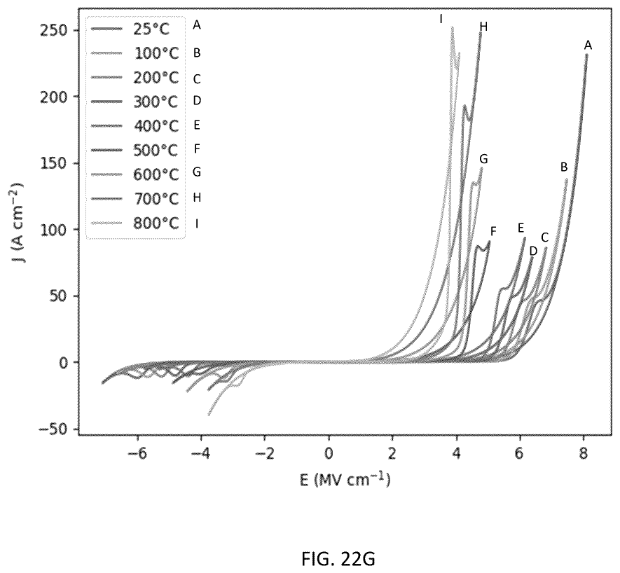

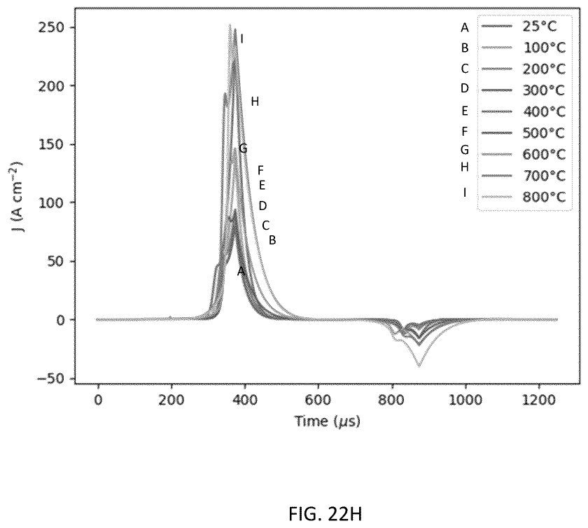

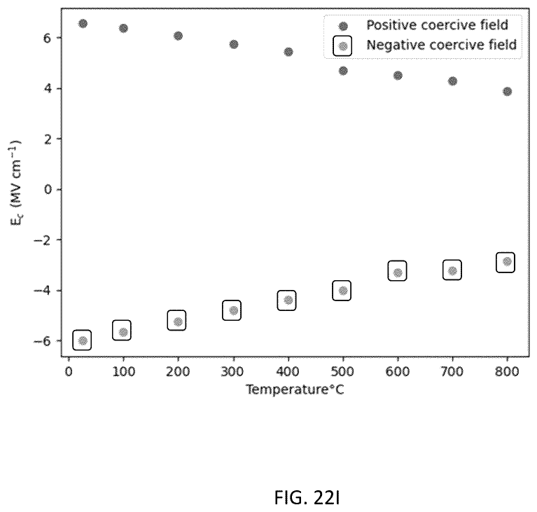

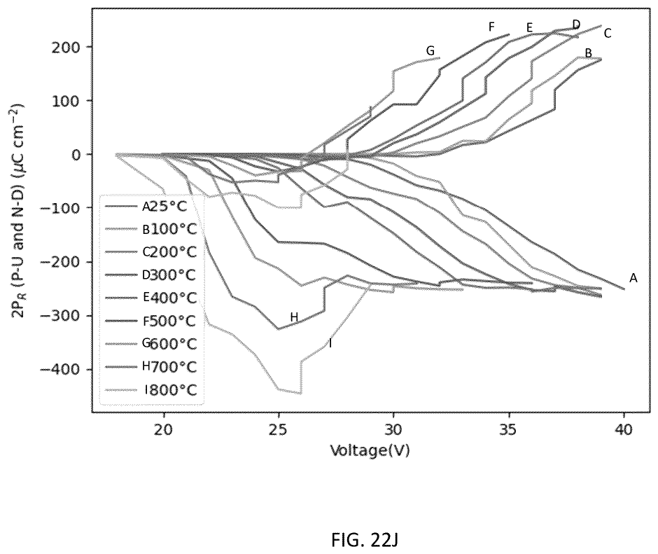

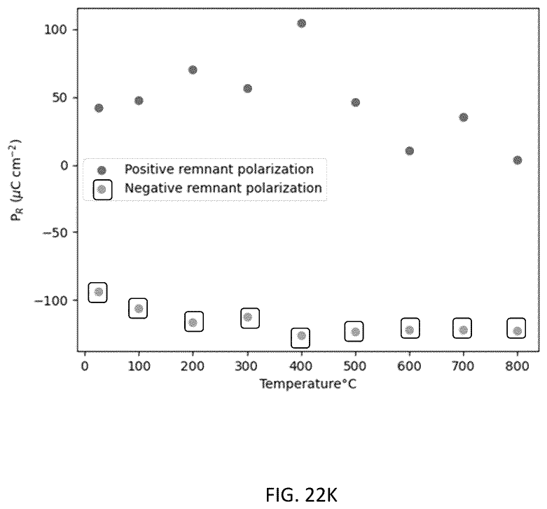

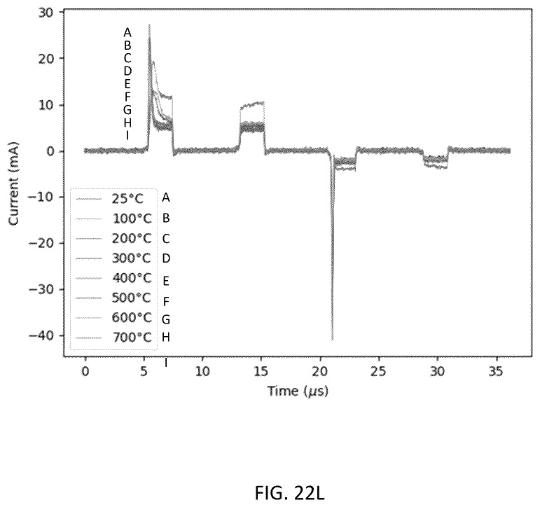

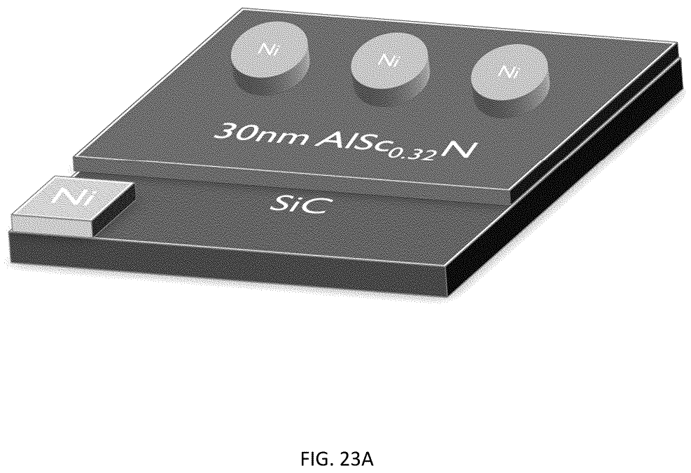

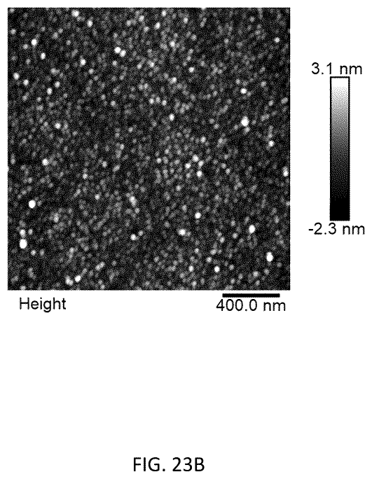

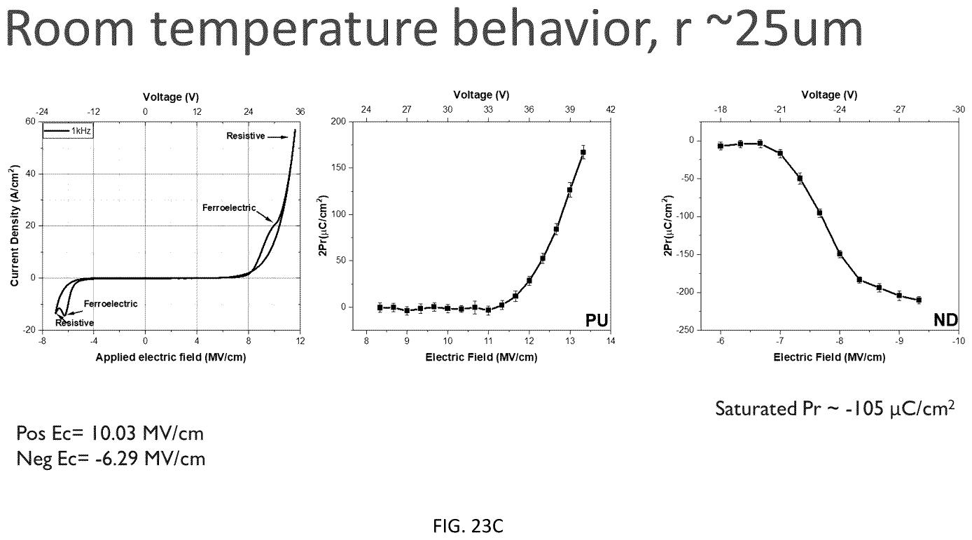

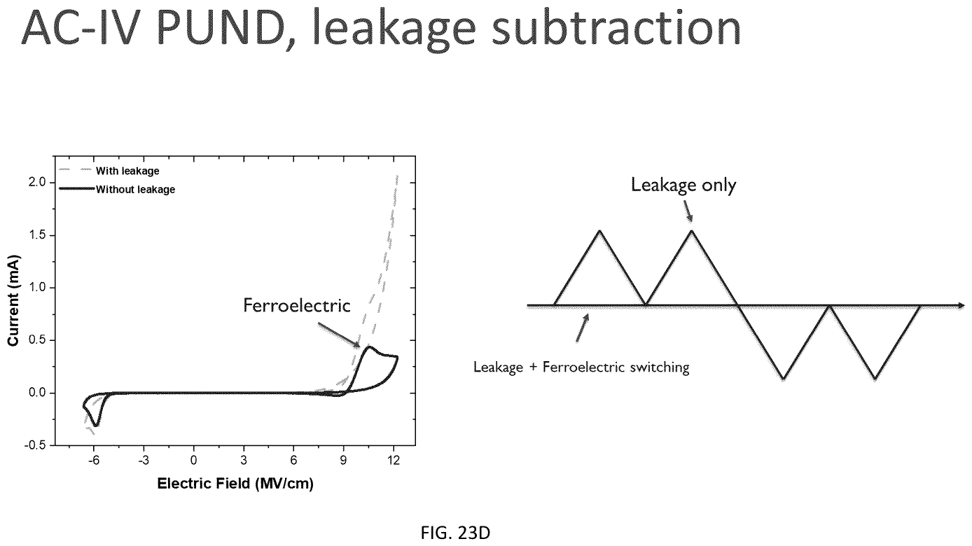

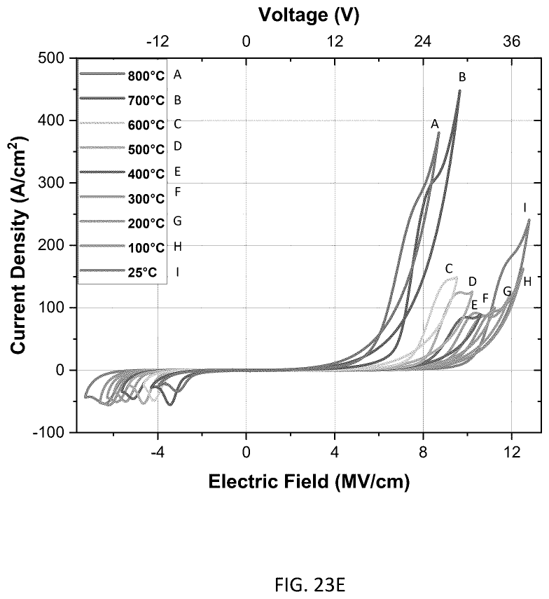

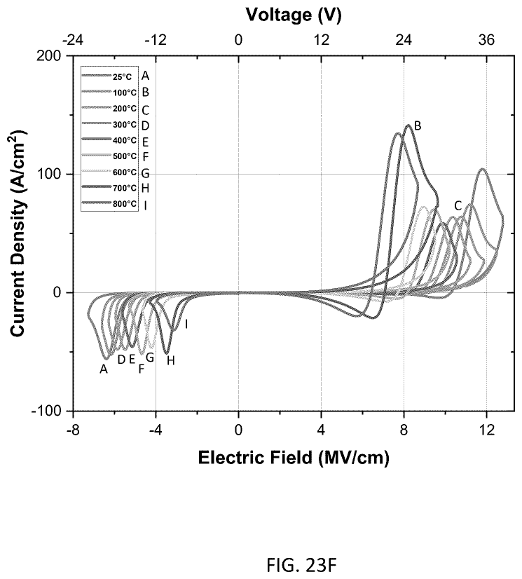

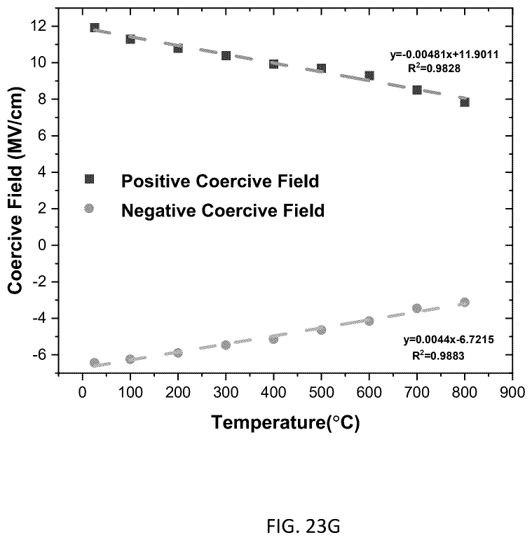

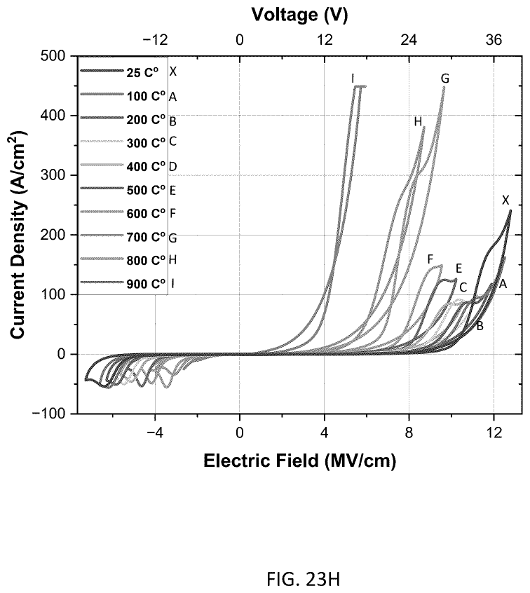

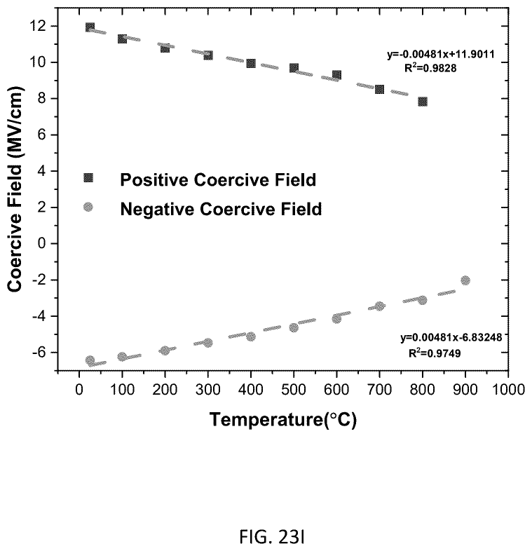

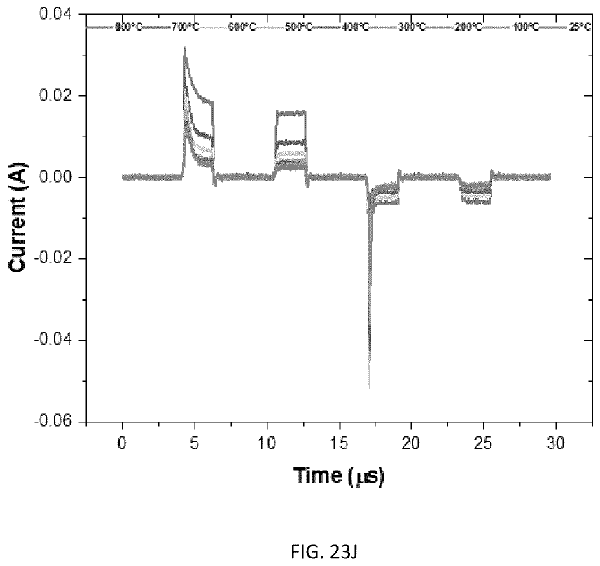

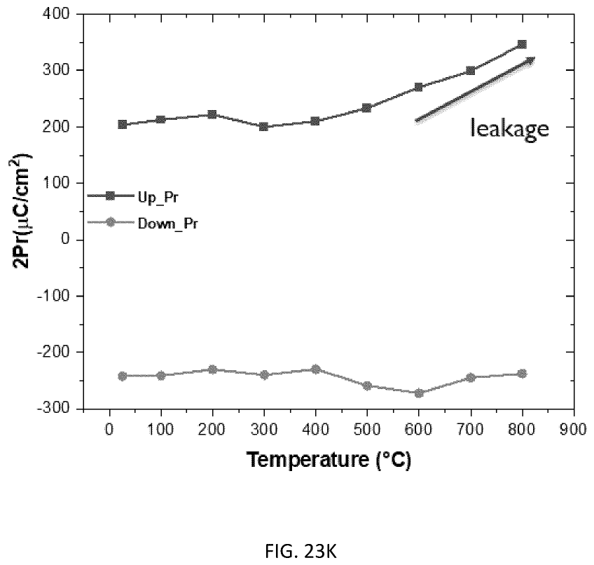

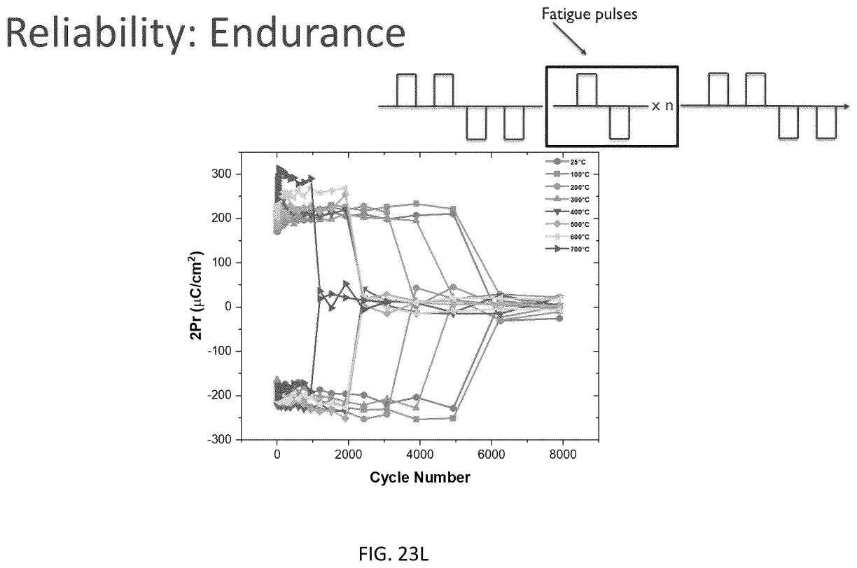

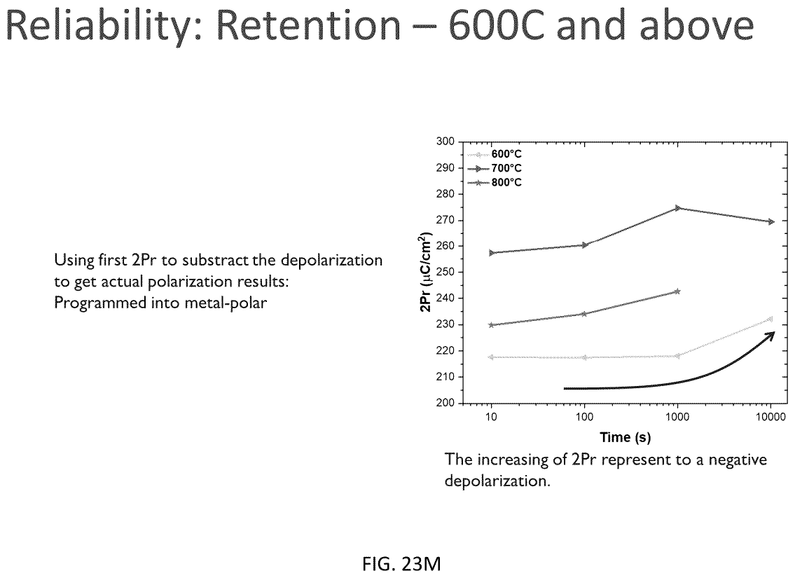

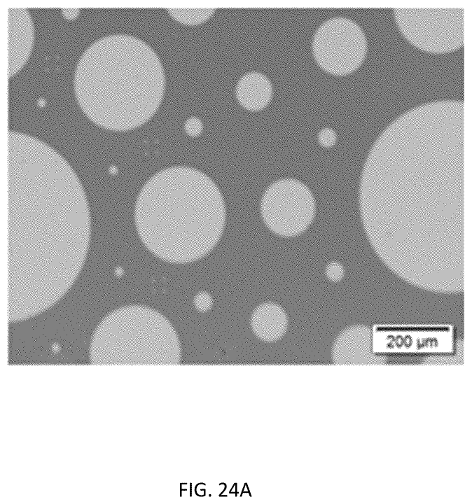

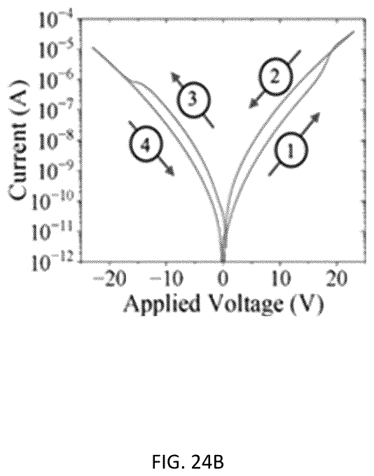

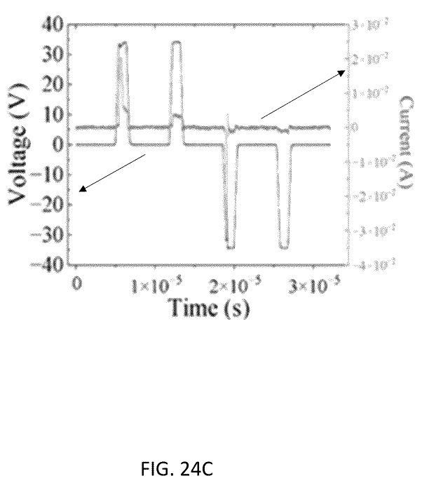

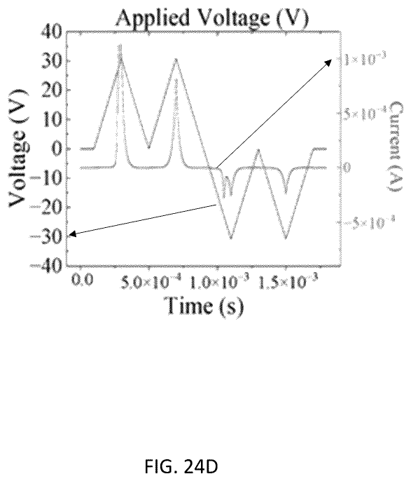

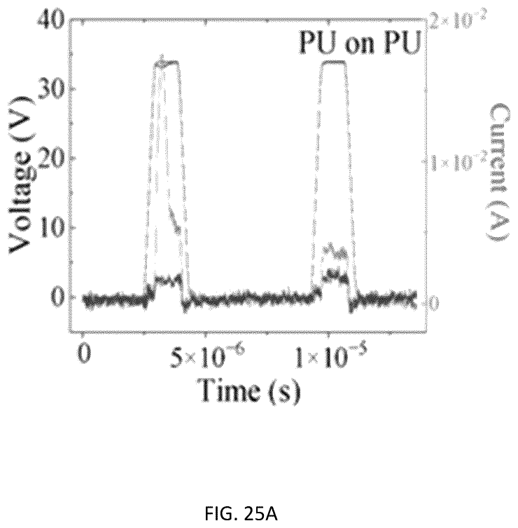

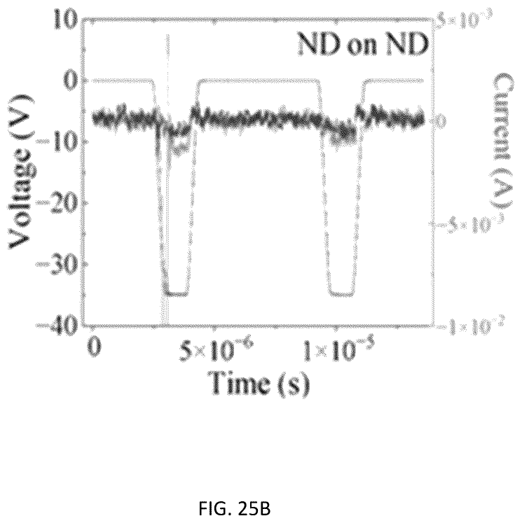

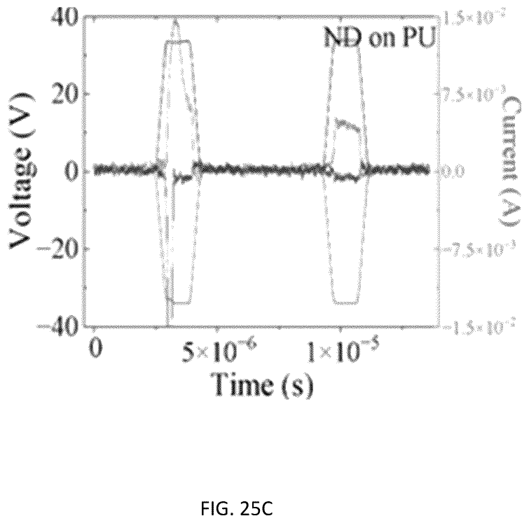

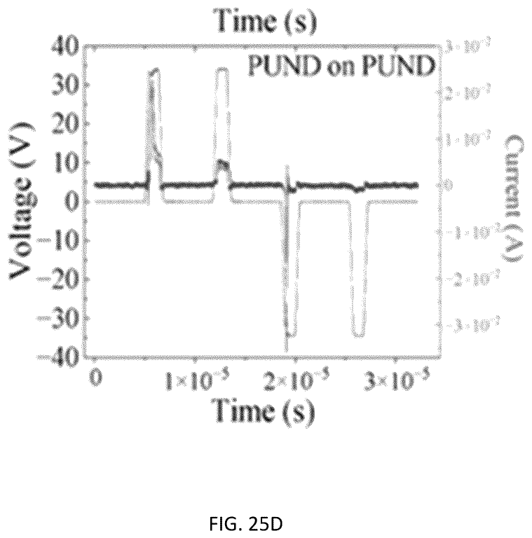

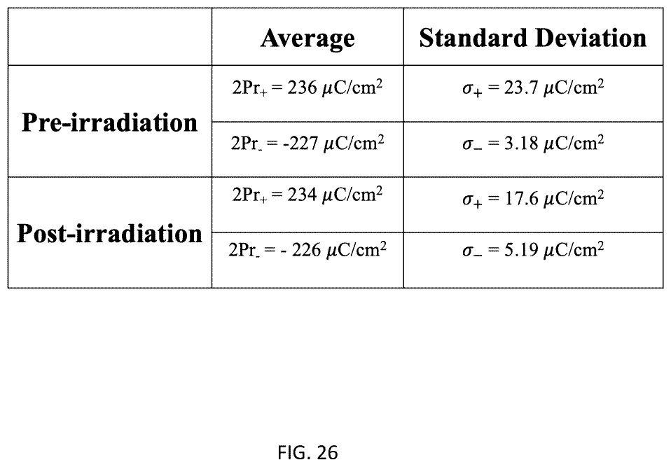

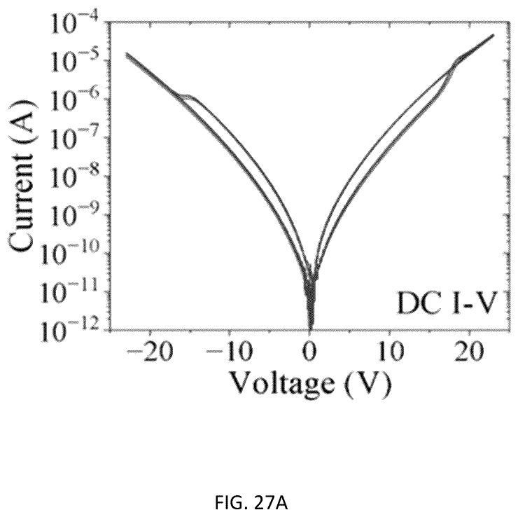

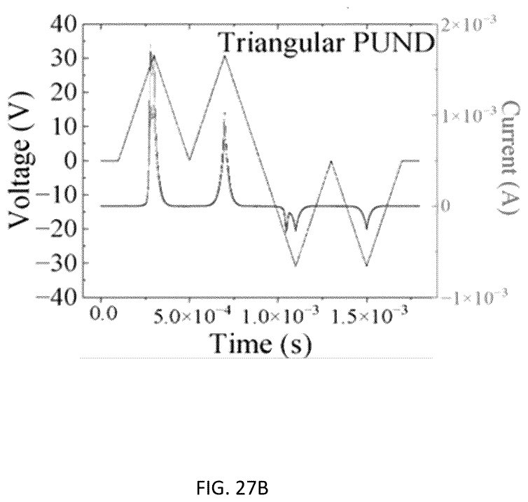

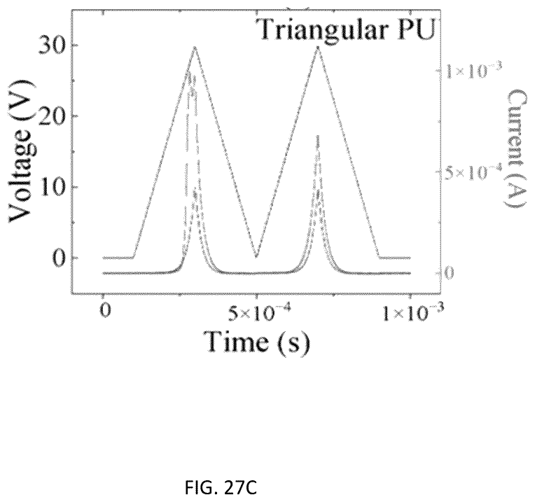

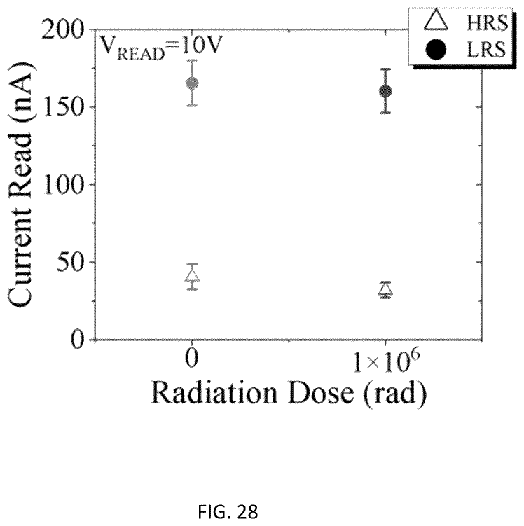

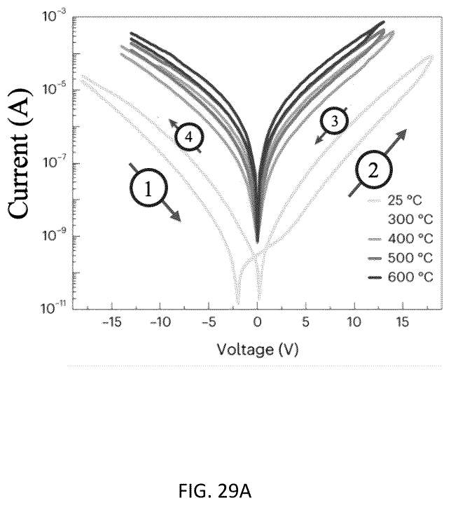

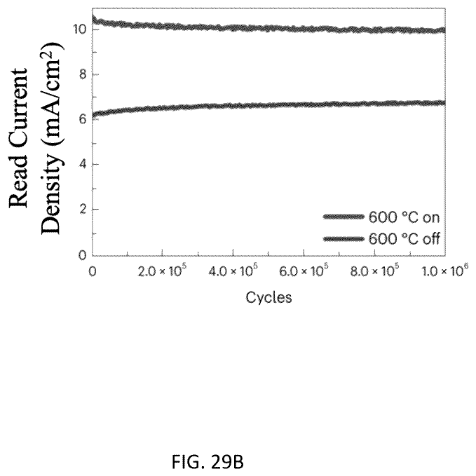

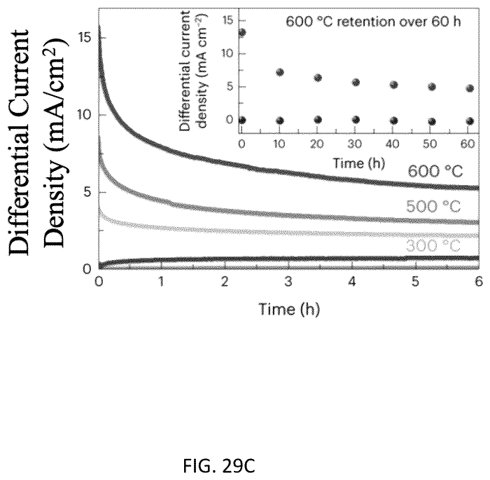

FIG. 22K provides example temperature vs. 2P_{R} data for a device according to FIG. 23A.

FIG. 23L provides example cycle number vs. 2P_{R} data for a device according to FIG. 23A.

FIG. 23M provides time vs. 2P_{R} data for a device according to FIG. 23A.

FIG. 24A: Top optical microscope image of the MFM Al0.64Sc0.36N devices of different sizes. FIG. 24B: Representative Current-Voltage (I-V) hysteresis measurement, with a voltage range ±23V. Numbers in crescent order indicate the sweeping direction to achieve high resistance state (HRS). FIG. 24C:Representative Positive-Up Negative-Down (PUND) measurement. Maximum applied poling voltage was ±34.5V. FIG. 24D: Representative triangle wave Positive-Up Negative-Down (PUND) measurement. Maximum applied poling voltage was ±31V.

FIG. 25A: Overlapping Positive-Up (PU) pulses on the same device before (red) and after (blue) irradiation. Poling voltage was 34V. FIG. 25B: Overlapping Negative-Down (ND) pulses on the same device before (red) and after (blue) irradiation. Poling voltage was 35V. FIG. 25C: Overlapping Positive-Up (PU) pulse and Negative-Down (ND) pulse on the same device before (red) and after (blue) irradiation respectively. Poling voltage was 34V. FIG. 25D: Overlapping Positive-Up Negative-Down (PUND) pulses on the same device before (red) and after (blue) irradiation. Poling voltage was ±34.5V.

FIG. 26. Average and standard deviation P_{R} values before and after irradiation across 5 individual devices.

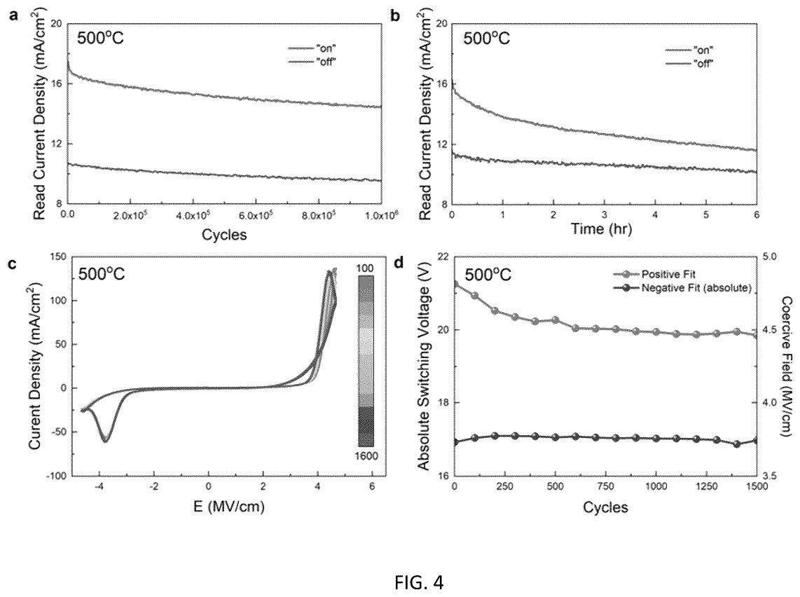

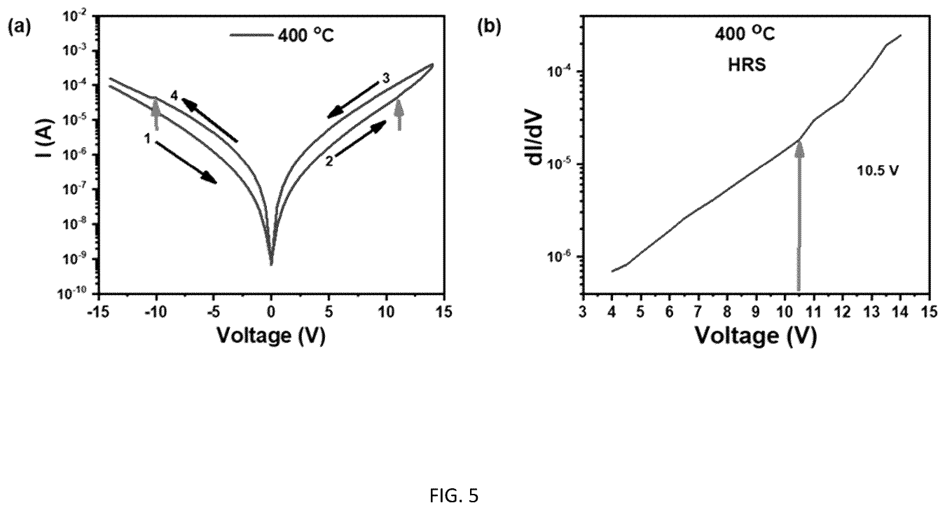

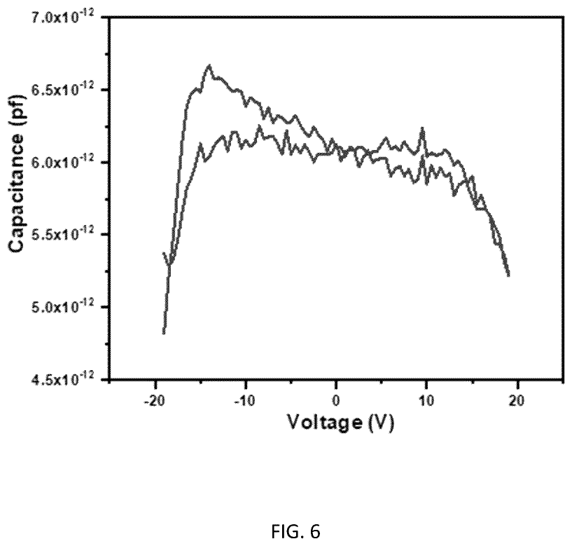

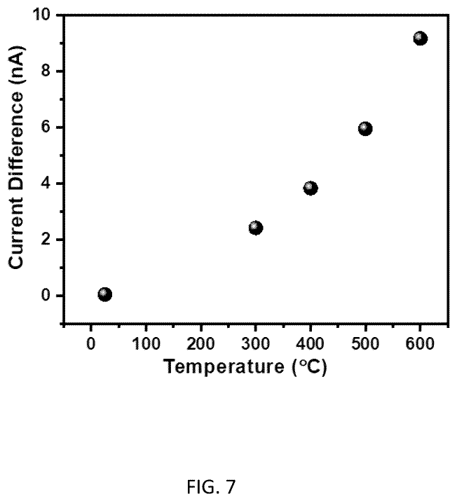

FIG. 27A: Overlapping hysteresis measurement on a device set in low resistance state (LRS) with voltage range ±23V before (red) and after (blue) irradiation. ON-OFF ratio for the LRS device in FIG. 4(a) shifts from 3.82 to 3.06 at 5V read voltage. FIG. 27B: Overlapping triangle wave Positive-Up Negative-Down (PUND) pulses on the same device before (red) and after (blue) irradiation. FIG. 27C: Overlapping Positive-Up (PU) pulses on the same device before (red) and after (blue) irradiation.

FIG. 28: Plot of read current from hysteresis measurements before (red) and after (blue) irradiation, along with standard deviation. Read voltage was set to 10V.

FIG. 29A: Hysteresis measurements of the Ni/Al0.68Sc0.32N/Pt (111) MFM devices at selected temperatures FIG. 29B: 106 read endurance cycles at 600° C. FIG. 29C: Retention behavior at 5 V read voltage at 300, 500, and 600° C., (inset) retention behavior at 600° C. over 60 hours.

### DETAILED DESCRIPTION OF ILLUSTRATIVE EMBODIMENTS

The present disclosure may be understood more readily by reference to the following detailed description of desired embodiments and the examples included therein.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing. All publications, patent applications, patents and other references mentioned herein are incorporated by reference in their entirety. The materials, methods, and examples disclosed herein are illustrative only and not intended to be limiting.

The singular forms “a,” “an,” and “the” include plural referents unless the context clearly dictates otherwise.

As used in the specification and in the claims, the term “comprising” can include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated ingredients/steps, which allows the presence of only the named ingredients/steps, along with any impurities that might result therefrom, and excludes other ingredients/steps.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently of the endpoints. The endpoints of the ranges and any values disclosed herein are not limited to the precise range or value; they are sufficiently imprecise to include values approximating these ranges and/or values.

As used herein, approximating language can be applied to modify any quantitative representation that can vary without resulting in a change in the basic function to which it is related. Accordingly, a value modified by a term or terms, such as “about” and “substantially,” may not be limited to the precise value specified, in some cases. In at least some instances, the approximating language can correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” can refer to plus or minus 10% of the indicated number. For example, “about 10%” can indicate a range of 9% to 11%, and “about 1” can mean from 0.9-1.1. Other meanings of “about” can be apparent from the context, such as rounding off, so, for example “about 1” can also mean from 0.5 to 1.4. Further, the term “comprising” should be understood as having its open-ended meaning of “including,” but the term also includes the closed meaning of the term “consisting.” For example, a composition that comprises components A and B can be a composition that includes A, B, and other components, but can also be a composition made of A and B only. Any documents cited herein are incorporated by reference in their entireties for any and all purposes.

Any embodiment or aspect provided herein is illustrative only and does not limit the scope of the present disclosure or the appended claims. Any part or parts of any one or more embodiments of aspects can be combined with any part or parts of any one or more other embodiments or aspects.

Illustrative Disclosure—Ferroelectric Diodes (MIM devices)

Non-volatile memory (NVM) devices that reliably operate at temperatures above 300° C. are currently non-existent and remains an unmet challenge in the development of high temperature resilient electronics. Many emergent technological frontiers in harsh environments require complex computing and sensing capabilities in-situ which are impossible without a reliable NVM device operating as high as 500° C. and beyond. Ferroelectric AlₓSc₁₋ₓN has utility in NVM devices, which can be operated at very high temperature (>500° C.) as it exhibits stable and high remnant polarization (P_{R}) above 100 μC/cm² with a ferroelectric transition temperature (T_{C})>1000° C. In the present study, we demonstrate an Al_{0.68}Sc_{0.32}N ferroelectric diode based NVM memory that can operate up to 600° C. The temperature dependent quasi-DC I-V curves exhibit ferroelectric diode behavior with clear ferroelectric switching up to 600° C. with distinguishable On and Off states. Pulse-IV and PUND measurements at temperatures from RT to 600° C. show ferroelectric switching in both positive and negative voltage pulses. The coercive field (Ec) from the Pulse I-V measurements is found to be ˜ be −5.83 (E_{C-}) and +5.98(E_{C+}) (+/−0.1) MV/cm at RT and found to decrease with increasing temperature. These devices exhibit high remnant polarization (>100 μC/cm²) which are stable at high temperature. At 500° C., these devices show ˜1 million read cycles and with stable On-Off ratio above 1 for >6 hours. Moreover, the operating voltages of the AlScN ferrodiodes are <15 V at 600° C. which is well matched and compatible with Silicon Carbide (SiC) based high temperature logic technology. These devices demonstrate herein show utility for NVM devices with fast switching speed, low switching energy along with the ability for multibit operation for extreme environment (>500° C.) applications.

Non-volatile memory (NVM) technologies that reliably operate at temperatures above 300° C. are not available commercially to date and remains a gap in the design of extreme environment electronics. There are numerous emerging harsh environment applications including aerospace, space exploration, oil and gas exploration, nuclear plants, mining and other applications that require complex computing and sensing capabilities in-situ. Current Silicon (Si) based micro(nano)electronics, utilizing complementary metal oxide semiconductor (CMOS) technology, encounter various substantial reliability challenges above 200° C. and cannot retain their functional properties at high temperatures as the number of thermally induced carriers exceeds the doping concentration level. In harsh environments, existing limitations in computation and data storage necessitate either on-board cooling or the placement of sensors/computations at a distance from the heat source and also adds significant mass and complexity, making it often impractical or infeasible. Extensive research has led to well-established material solutions for logic transistors, which can effectively operate at temperatures as high as 800° C., but the absence of memory devices suitable for information storage hinders the execution of intricate computing operations at these elevated temperatures.

Nonvolatile random-access memory (NVRAM) relying on magnetic, FLASH, phase-change, and resistive switching mechanisms exhibits rapid degradation at temperatures around 200° C. Active research and development are focused on exploring and developing NVM technologies capable of storing information at elevated temperatures while remaining compatible with SiC electronics. SiC electronics, being the most mature and preferred high-temperature logic platform, further emphasizes the importance of this pursuit.

Microelectromechanical system-based flash memory (MEM-FLASH) and nanogap resistance switching (NGS) technologies show promise for NVM applications at high temperatures. But these approaches have drawbacks due to the presence of moving parts and the challenges associated with operating in diverse atmospheres. Among the NVM technologies explored at temperatures exceeding 200° C., three have received significant attention: flash memory, resistive memory based on oxides, and ferroelectric memory. Among these, only flash memory, which operates at approximately 200° C., is the commercially available product.

Ferroelectric materials exhibit remanent polarization, field-driven switching, along with their ability to retain the switched state for long time, makes them well-suited for low-power nonvolatile memory applications as they exhibit fast switching speed, low switching energy, and can be used in multibit operation. To meet the temperature demands of harsh environment applications, ferroelectric materials with high Curie temperatures (T_{C}) are required as ferroelectric polarization and switching cannot be observed if the device temperature exceeds the T_{C}. Ferroelectric memory technologies utilizing perovskite and/or fluorite structured oxides such as Pb(Zr₁₋ₓTiₓ)O₃ (PZT), BiFeO₃ and (Hf,Zr,Si)O₂ have been investigated but these materials face temperature limitations. Among the perovskite oxides, PZT is one of the best ferroelectric oxide materials having maximum remanent polarization of ˜70 μC/cm² with ferroelectric Tₑ less than 500° C.

The utilization of PZT in FE memory technology is still in the early stages of development but is not fully compatible with complementary metal-oxide semiconductor (CMOS) technology and back-end-of line integration (BEOL) integration because of high crystallization temperatures, lead inclusion, and weakly bound oxygen. In addition, PZT suffers from the destabilization of the polar structure, enhanced domain wall mobility and chemical instabilities at higher temperature. Among the other perovskite ferroelectrics, bismuth iron oxide (BiFeO₃) is one of the mostly studied lead-free ferroelectric materials having a high Curie temperature of ˜830° C. However, this material has several drawbacks.

The first report in 2011 on the discovery of ferroelectricity in doped hafnium oxide has opened up exciting technological possibilities, enabling the integration of ferroelectric materials into commercial technologies down to 28 nm, 22 nm nodes, and beyond. Some observed a notable decrease in P_{R} above 623 K (˜350° C.) in a mixed zirconium hafnium oxide (Hf₁₋ₓZrₓO₂) system. In this study, it is also reported that the ferroelectric T_{C} is dependent on ZrO₂ content, but it does not exceed 800 K (˜527° C.) irrespective of the composition. In addition, doped hafnium oxide based materials exhibit P_{R} of 10-50 μC cm⁻² In another report, the ferroelectric T_{C} of HZO is predicted to be above 1000° C., and the HZO/β-Ga₂O₃ ferroelectric FET devices can be operated up to 400° C., but this device shows a sharp decline in polarization at 300° C. Hence, perovskite and fluorite structured oxides are not suitable to be utilized in the NVM devices for harsh environment applications (>500° C.).

Here, a 45 nm thick Al_{0.68}Sc_{0.32}N ferroelectric diode based NVM memory is demonstrated that can operate up to 600° C. The devices are composed of metal insulator metal (MIM) structures of Ni/Al_{0.68}Sc_{0.32}N (45 nm)/Pt (111) on 4″ Silicon wafers. In this letter, we report a detailed temperature dependent ferroelectric and NVM characteristics up to 600° C. The temperature dependent DC I-V curves exhibit ferroelectric diode behavior with clear ferroelectric switching up to 600° C. with distinguishable ON and OFF states. At 500° C., these devices show 1 million read cycles and with stable On-Off ratio for >6 hours. The operating voltages of these devices are well matched and compatible with SiC based high temperature logic technology and promising for several harsh environment applications.

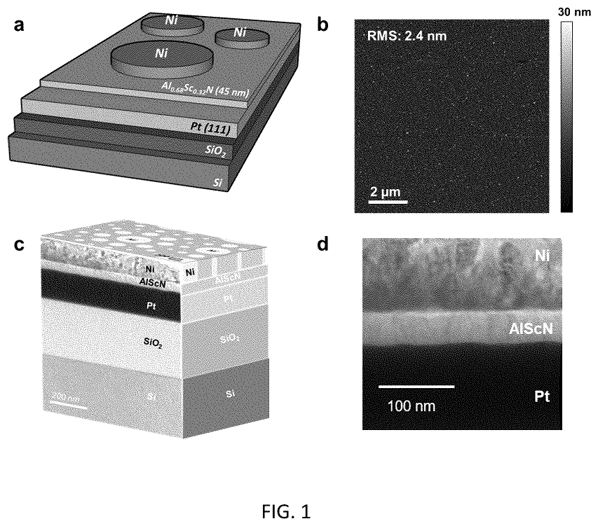

A schematic depiction of the Ni/Al_{0.68}Sc_{0.32}N/Pt NVM devices investigated in this study is shown in FIG. 1(a). First, a 45 nm thick Al_{0.68}Sc_{0.32}N film was deposited by co-sputtering from separate Al and Sc targets onto a commercially available 150 nm Pt(111)/Ti/SiO₂ on Si(100) substrate. Top electrodes (TE) were then patterned using standard photolithography, followed by sputtering of a Ni (100 nm) metal top electrodes and lift-off process. Circular top Ni electrodes of various sizes were patterned on the AlScN surface. FIG. 1(b) presents the surface morphology of the top AlScN layer in an example Ni/AlScN/Pt device. Surface topography reveals a smooth and uniform surface with a root mean squared roughness (Rrms) of ˜2.4 nm. The heterostructure's upper surface exhibits nano-scale smoothness and homogeneity, devoid of any microcracks, pores, or holes. A composite image of the AlScN MIM device displaying each layer with a cross sectional TEM on the left and a labeled schematic on the right with an overlaying optical microscopic image on the top surface of AlScN (FIG. 1(c)). A cross sectional TEM image of the MIM device is shown in FIG. 1(d). The TEM image confirms the existence of all the layers and their respective thicknesses. The thickness of the Al_{0.68}Sc_{0.32}N layer is found to be ˜45 (±2) nm. A native oxide layer of thickness ˜4 nm is observed on the surface of AlScN film as the films were exposed to air before top Ni electrode deposition.

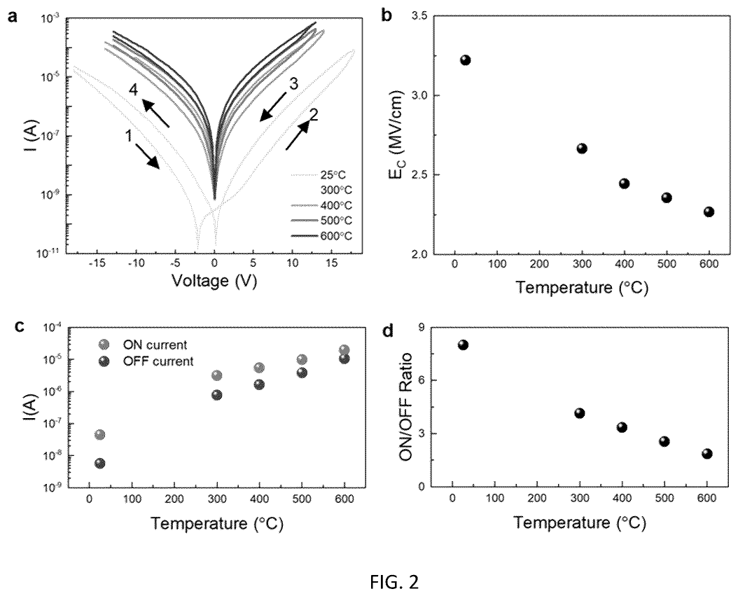

To investigate the impact of temperature on ferroelectric diode characteristics, ferroelectric switching, and leakage current behavior, quasi-DC (0.01 Hz) I-V hysteresis measurements were performed at different temperatures (25-600° C.) on the MIM devices(FIG. 2(a)). Upon programming with a positive voltage sweep (1 to 2), the device undergoes a transition from high-to-low resistance, accompanied by a polarity shift from a negative-forward diode to a positive-forward diode. Likewise, during a negative voltage sweep, the device exhibits a polarity change from a positive-forward diode to a negative-forward diode. At all temperatures, ferroelectric diode-like behavior can be clearly observed in the Al_{0.68}Sc_{0.32}N devices from the change in the resistance upon ferroelectric switching. Positive coercive field (E_{C+}) values were calculated using the first derivative of current with respect to voltage and their temperature dependence of E_{C+} is depicted in FIG. 2(b). The E_{C+} values at room temperature (RT, −25° C.) and at 600° C. are found to be 3.16 and 2.05 (+/−0.1) MV/cm, respectively, and decrease with increasing temperature. The E_{C+} decreases linearly with increasing temperature, indicating the increased thermal energy overcomes the activation barrier and facilitates the crystal dipole transformation associated with domain switching. The decrease of coercive field high temperature can also be correlated to the thermally activated increased domain wall motion. The voltage dependence of capacitance (C-V) measurement exhibits a butterfly shaped loop indicating a non-linear capacitor. The decrease of capacitance with increasing applied voltage, indicating ferroelectric polarization switching.

FIG. 2(c) shows the temperature dependence of On and Off leakage currents at 5V read voltage, with both the On and Off currents increasing with rising temperature. The On-Off ratio of the AlScN MIM devices at 5V read voltage was calculated, and its temperature dependence is presented in FIG. 2(d). The device exhibits an On-Off ratio of 8.06 at RT and 1.87 at 600° C., and it decreases linearly with increasing temperature. This reduction in On-Off ratio primarily results from an increase in overall leakage current as thermal energy enhanced carrier mobility within the AlScN⁴³. De-trapping of charges owing to domain wall motion and relaxation of the AlScN crystal lattice around defect sites may also contribute to an overall increase in current at high temperatures. Regardless, while the engineering of devices with enhanced On-Off ratios is the subject of our ongoing investigation, the absolute current difference does not diminish with increase of temperature. A practical MIM device can thus utilize a reference capacitor in the Off state to subtract a baseline and read successfully at all temperatures.

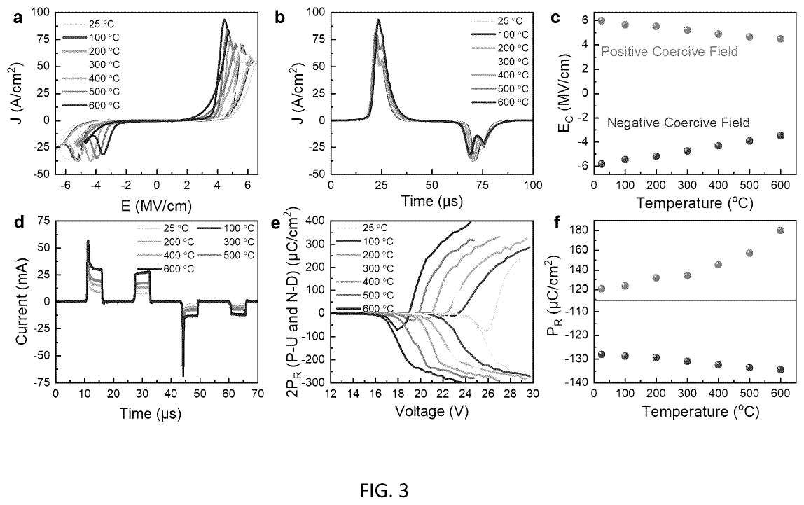

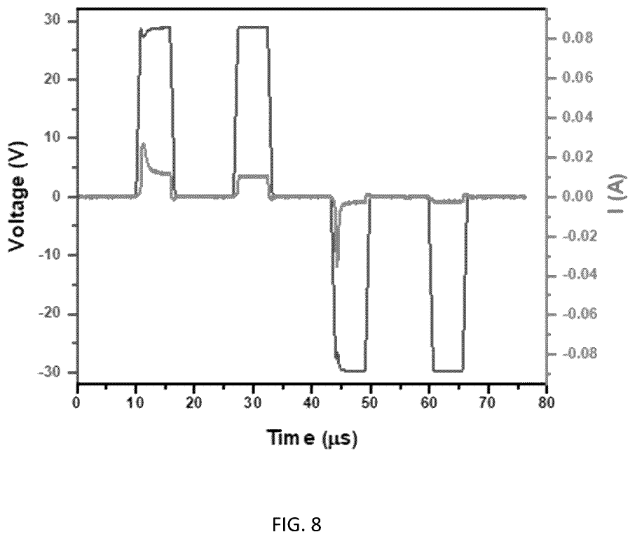

Pulse-IV, in contrast to DC-IV, provides a dynamic characterization approach to investigate the electrical responses ferroelectric devices under high voltage ramp rates, allowing the differentiation of domain switching dynamics from leakage and capacitive charging contributions. Pulse-IV measurements were conducted across a temperature range from room temperature (˜25° C.) to 600° C. in 100° C. increments. These tests were performed at 10 kHz on 100 μm diameter devices, incrementally increasing the voltage until the device failed. At this ramp rate, leakage current is negligible compared to switching and capacitive charging currents until very high voltages, enabling direct observation of the switching voltage. FIG. 3(a and b) depicts selected traces before gaining leakage tails, displaying the coercive field as the maximum and minimum values for on and off switching, respectively. Apparent E_{C} increases with ramp rate due to kinetic effects (further details with various ramp rates are available in FIG. 8). FIG. 3(c) presents the measured E_{C+} and E_{C-} plotted against temperature and both sides exhibited a linear response with respect to temperature as was observed with the DC-IV.

Positive-Up Negative-Down (PUND) measurements offer a time-resolved approach to probe the signature of ferroelectricity and to explore the polarization dynamics of AlScN ferroelectric devices, enabling the observation of domain kinetics and domain switching dynamics separated from leakage and capacitive charging. PUND measurements were performed at each temperature, starting at 5V magnitude and increasing until device failure. FIG. 3(d) illustrates select traces that clearly demonstrate ferroelectric switching on both positive and negative pulses. Given that the onset voltage for switching and leakage both vary with temperature, PUND results were compared using pulse voltages normalized to the onset of diode behavior, defined as the point where the pulse current becomes three times larger than the capacitive charging current. PUND traces selected as “saturated” had maximum voltages of 126% of this onset value for each temperature. These onset voltages were found to be mostly consistent with the pulse-IV results, dropping approximately 1.3V per 100° C. increase. We chose 126% to create the most robust and comprehensive dataset, as this voltage represents the maximum similar saturation available at all temperatures, as the devices do not fully saturate before device failure. FIG. 3(e) illustrates the double remnant polarization (2P_{R}) traces at all voltages and temperatures, with each trace ending at the point of device failure. FIG. 3(f) plots the remnant polarization versus temperature for both the up and down pulses. As predicted, the magnitudes of both increase slightly with temperature due to the rise in overall leakage current coupled with incomplete saturation.

The precise mechanisms underlying the failure of these devices at high voltage and after numerous cycles, as well as strategies to improve their lifespan, remain subjects of ongoing investigation. The failure mode consistently involves a dielectric breakdown leading to unrecoverable short circuit between the top and bottom pad and can be induced by overvoltage or excessive pressure from the probe tip on the top pad. Breakdown has been observed at both positive and negative voltages, though usually above the switching voltage. Unlike current, the failure threshold varies significantly from one device to another, though the measurements depicted in FIGS. 3 and 4 are representative. Overall, smaller devices appear to be more resilient, likely due to the decreased number of defects within their AlScN layer, reducing the opportunities for failure.

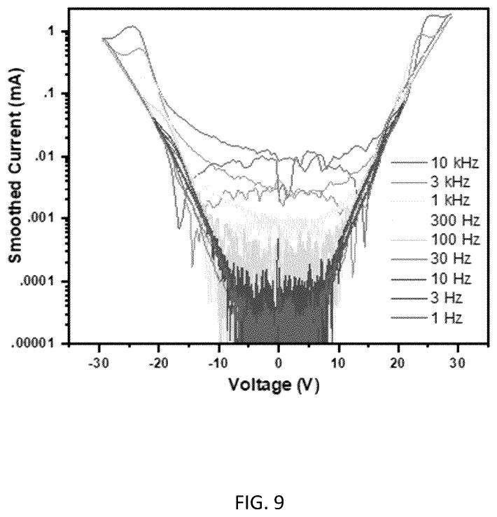

Despite this, read operations can be achieved at low voltages that do not induce failure. Reads taken at 5V yield a current density of 10-17 mA/cm², providing a current of 3-6 μA on 100 μm diameter pads, depending on the device's state. This is sufficient for facile measurement without stressing the device. The evolution of these currents over cycles and time is shown in FIGS. 4(a) and (b), respectively, at 500° C. (representative current vs time data available in FIG. 9). The 1M read retention was performed with separate runs for the on and off devices due to timing restrictions on the DAQ. >1M cycles of 100 μs width were successfully read over the course of approximately two minutes, showing a modest decrease in the on state within the first 20k cycles, followed by a slight continuing decrease in both On and Off state current density. We attribute this slow slope to AlScN self-annealing at high temperature, though the higher drop in the On state device likely indicates heightened domain relaxation. The 6-hour endurance test (FIG. 4(b)) was performed simultaneously with on and off devices, but due to limitations in the hardware, a several-minute gap occurred between the write state and the read tests. A cluster of 25 consecutive 5 V pulses of 100 μs width was performed every 15 seconds and averaged to produce the current data. The On state current continues to drop throughout the test, reducing the on/off ratio to only 1.15 by the end, but a detectable gap is still evident, and the state is readable for logic device purposes.

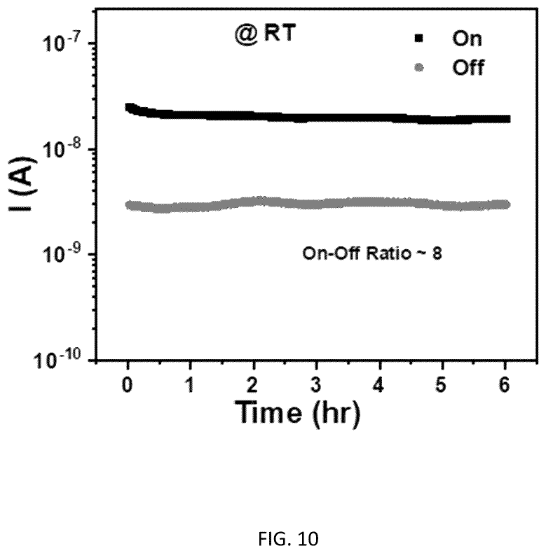

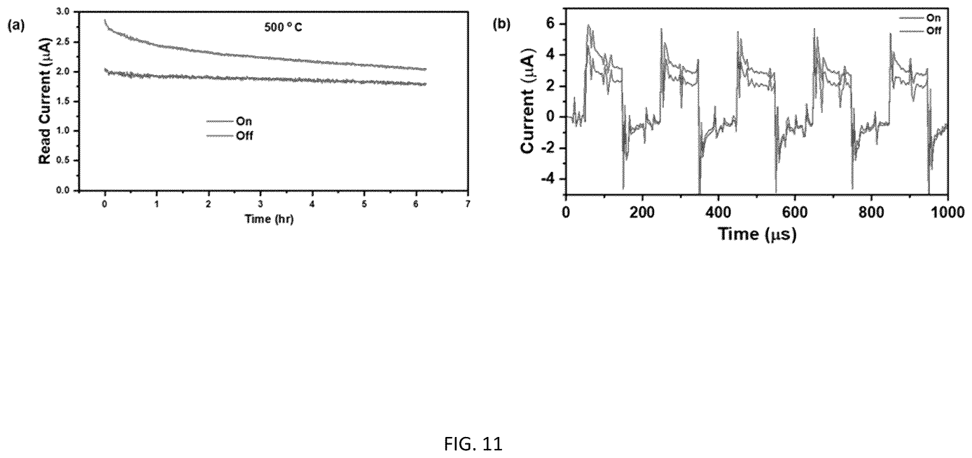

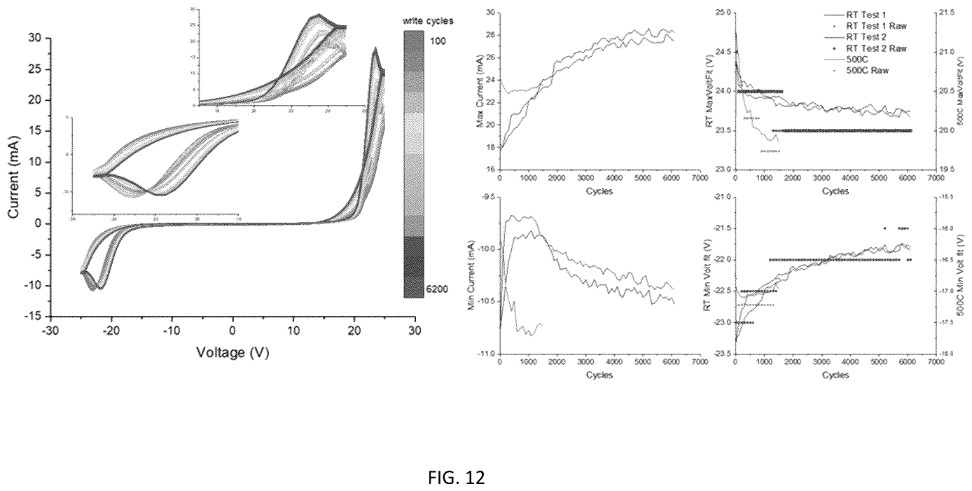

Write longevity (FIGS. 4(c) and (d)) was found to be sensitive to both write voltage and increasing temperature. Tests were performed in groups of 100 write pulses, followed by a test pulse-IV to determine whether the device survived and look for changes. At room temperature on 100 μm diameter pads, 25 V write pulses survived for 6033±379 cycles (further details in FIG. 10). At 500° C., devices survived 1433±413 write cycles at 19V (FIG. 4(c)) and 1233±58 cycles at 20V write voltage. The coercive field (E_{C}) values for the positive switching were observed to shift more than the negative E_{C} during the write longevity testing, decreasing from 4.72 MV/cm (21.25 V) to 4.41 MV/cm (19.85 V) throughout the run. The wakeup effect is observed in the first few cycles, but the high-temperature long-term E_{C+} drift is higher than observed at room temperature, and has a reverse trend at the onset of E_{C-}, which may be due to repeated cycles inducing domain wall motion which de-pins domains. But no evident change occurred just before failure, and no obvious sign of impending failure is observed in the previous pulse.

We demonstrated ferroelectric diode based NVM memory device with a MIM structure of Ni/Al_{0.68}Sc_{0.32}N/Pt (111) that can operate up to 600° C. with distinct On and Off states. At elevated temperatures, these devices demonstrate high remnant polarization. At 500° C., these devices exhibit an impressive 1 million read cycles and maintain a stable On-Off ratio for over 6 hours. Even at 600° C., the operating voltages of our devices remain below 15 V, demonstrating compatibility with SiC electronic integration and packaging. The devices demonstrated herein enable digital computing systems capable of operating at temperatures and in a variety of harsh environment applications.

### Methods

Growth of Al_{0.68}Sc_{0.32}N

The AlScN thin films containing 32% Sc concentration (Al_{0.68}Sc_{0.32}N) were grown on Pt (111)-oriented wafers using a physical vapor deposition (PVD) system. The 4-inch Pt (111)/Ti/SiO₂/Si wafers were obtained from MTI Corporation. First, a 45 nm thick Al_{0.68}Sc_{0.32}N film was deposited on the wafer by co-sputtering from separate Al and Sc targets. The co-sputtering was carried out in an Evatec CLUSTERLINEVR 200 II pulsed DC PVD system with a power of 1000 W for Al and 655 W for Sc. The deposition took place at a temperature of 350° C. under a vacuum of 8×10⁻⁴ torr, with a flow of N₂ gas (20 sccm).

Following the deposition of the Al_{0.68}Sc_{0.32}N film, a 50 nm thick Al capping layer was deposited on the top of it. This deposition was performed at a temperature of 150° C. with an Ar gas flow of 20 sccm. It is worth noting that the deposition of the Al capping layer was done without breaking the vacuum, ensuring prevention of surface oxidation on the Al_{0.68}Sc_{0.32}N film.

### Device Fabrication

To create the pattern for the top electrode, the Al capping layer underwent etching using a 1% HF solution. Subsequently, the Al_{0.68}Sc_{0.32}N/Pt (111) samples were coated with a negative photoresist (NR71-3000p), followed by photolithography to define the top electrode pattern. After development using a RD6 developer, a 100 nm thick layer of Ni was deposited as the top electrode metal using a sputtering system (Kurt J. Lesker PVD 75 PRO-Line Sputterer), The deposition rate was set at 2.5 Å/s and took place under low pressure condition of 5×10⁻⁷ Torr. Then, the samples were immersed in a remover PG for approximately 10 min, gently shaken to lift off any excess metal and then rinsed with deionized water. Finally, the samples were dried using N₂ blowing.

### AFM and Scanning TEM Characterizations.

To study the surface morphology of the top layer of Al_{0.68}Sc_{0.32}N MIM device, AFM topography scans were performed on the AlScN sample using an OmegaScope Smart SPM (AIST-NT) setup. Additionally, scanning TEM characterization and image acquisition were conducted using a JEOL F200 instrument operated at 200 kV acceleration voltage. A cross-sectional TEM sample was prepared using TESCAN S8000X system equipped with a Ga plasma focused-ion-beam. Pt protecting layers were deposited using electron-beam and ion-beam techniques to ensure the preservation of the sample top surfaces and prevent heating effects during focused-ion-beam milling. The focused-ion-beam milling of the lamella was carried out at 30 keV. Subsequently, an in-situ lift-out technique was used with the assistance of a Kleindiek probe manipulator. The final steps involved thinning and cleaning the lamella at energies of 10 keV and 5 keV, respectively.

### Device Characterizations

In order to characterize the device performance, several electrical measurements including current-voltage (I-V), capacitance-voltage (C-V) and positive-up and negative-down (PUND) measurements were conducted at room temperature. The PUND test involved a voltage waveform consisting of four monopolar pulses. The pulse width, rise/fall times, and delay (interval between subsequent pulses) were specified as 5 μs, 800 ns, and 10 μs, respectively. The measurements were performed in air in a Cascade Microtech (MPS-150) probe station using a Keithley 4200A semiconductor characterization system. For temperature-dependent measurements such as DC I-V, pulsed I-V, PUND, the device was placed in a vacuum environment of approximately 10⁻⁴ Torr. These measurements were conducted in a custom MicroXact high temperature probe station using tungsten probes. PUND and DC-IV characterization was performed using the same Keithley 4200A system. Pulsed I-V and write longevity measurements were performed with a Radiant Technologies Multiferroic II Ferroelectric Tester at 10 kHz unless otherwise specified. Read endurance measurement at RT was carried out by a Keithley 4200A semiconductor characterization system with a ±19 V DC pre-soak, followed by 5V 100 μs square pulses for the read current. Similarly, the 500° C. read endurance measurements were performed with a Keysight B1500A Semiconductor Parameter Analyzer to accommodate limitations in the high temperature probe station consisted of simultaneously measuring On and Off electrodes with a ±13 V DC pre-soak, followed by 5V 100 μs square pulses for the read current. Read retention measurements were performed with a Measurement Computing USB-1808X DAQ with the 5V 10 kHz waveform provided by the Keysight B1500A on electrodes switched in the same manner as the read endurance measurements. All electrical measurements were carried out on top Ni circular electrodes with a 100 μm diameter unless otherwise specified, which were positioned on the Al_{0.68}Sc_{0.32}N/Pt samples. Maximum PUND, I-V, and write voltages were varied with changing temperature to account for temperature-variable switching voltage.

Below are exemplary, non-limiting data for a MIM Device: Ni/Al_{0.68}Sc_{0.32}N/Pt (111) MIM device.

Coercive electric field ranges for the negative field direction (in MV/cm): −2.94 to −5.83 MV/cm (RT).

Coercive electric field ranges for the positive field direction (in MV/cm): 3.16 to 5.98 MV/cm (RT) (The temperature dependence of positive and negative coercive electric field obtained from DC IV and pulse IV are presented in Table 1 and 2).

Saturated remnant polarization ranges (in μC/cm²): Positive Remnant Polarization ˜120 μC/cm²; Negative Remnant Polarization ˜−128 μC/cm² (The temperature dependence of positive and negative remanent polarization (P_{R}) are presented in Table 3).
Read cycling—>10⁶ cycles (for both RT and 500° C.)
Retention time—>6 hours (for both RT and 500° C.)
Write endurance—6033±379 cycles at RT and 1433±413 cycles at 500° C.

TABLE 1
Temperature dependence of positive and negative
coercive field (E_{C}) from DC IV curves

| | Positive coercive | Negative coercive |
|---|---|---|
| Temperature (° C.) | field (MV/cm) | field (MV/cm) |
| 25 | 3.16 | −2.94 |
| 300 | 2.55 | −2.44 |
| 400 | 2.33 | −2.11 |
| 500 | 2.11 | −1.88 |
| 600 | 2.05 | * |

TABLE 2
Temperature dependence of positive and negative
coercive field (E_{C}) from pulse IV curves

| | Positive coercive | Negative coercive |
|---|---|---|
| Temperature (° C.) | field (MV/cm) | field (MV/cm) |
| 25 | 5.98 | −5.83 |
| 100 | 5.65 | −5.45 |
| 200 | 5.51 | −5.2 |
| 300 | 5.22 | −4.77 |
| 400 | 4.89 | −4.33 |
| 500 | 4.66 | −3.93 |
| 600 | 4.47 | −3.50 |

TABLE 3
Temperature dependence of positive and
negative remanent polarization (P_{R})

| | Positive Remanent | Negative Remanent |
|---|---|---|
| Temperature (° C.) | Polarization (μC/cm²) | Polarization (μC/cm²) |
| 25 | 120.56 | −128.08 |
| 100 | 123.40 | −128.77 |
| 200 | 131.80 | −129.34 |
| 300 | 134.06 | −130.94 |
| 400 | 145.00 | −132.49 |
| 500 | 156.94 | −133.68 |
| 600 | 180.06 | −134.54 |

### Illustrative Disclosure—SiC Devices

Also described herein is description of oriented growth and switching of thin (˜30 nm) ferroelectric (FE) Aluminum Scandium Nitride (AlScN) films on degenerately doped 4H Silicon Carbide (SiC) wafers. Metal ferroelectric semiconductor (MFeS) capacitors comprising of Al/Al_{0.68}Sc_{0.32}N/4H—SiC are fabricated and tested on these sputter-deposited films. The devices exhibit asymmetric coercive electric field values of −5.55/+12.05 MV cm⁻¹ at 100 kHz for FE switching, accounting for the voltage divided by the depletion region of the semiconducting SiC substrate under positive voltages. Additionally, the FE AlScN exhibits a remnant polarization of 110.17 μC cm⁻², measured via a voltage-pulsed positive-up negative-down (PUND) measurement. We further investigate the reliability of the reported devices, revealing an endurance of approximately 3700 cycles and a retention time exceeding 10⁶ seconds without any significant loss of polarization. Our findings demonstrate the bipolar switching of Al_{0.68}Sc_{0.32}N on doped SiC substrates establishing a foundation for monolithic integration of non-volatile memory with SiC-based logic devices appropriate for high temperature operation, as well as for high-power switching, memory, and sensing applications.

Non-volatile memory (NVM) devices have been in great demand and intensively investigated in recent years due to the rise of data-centric computing applications such as Machine-Learning and Artificial Intelligence. The emerging candidates for the next generation nonvolatile memories include ferroelectric (FE) random-access memory (FeRAM), magnetic random-access memory (MRAM), resistive random-access memory (RRAM), and phase change memory (PCM).

Among them, FeRAM stands out due to its low power consumption, fast operation speed, high endurance, and good retention. FeRAM employs ferroelectric materials that can switch their polarization states in response to an electric field, allowing the storage of information in the form of electrical charge. A large remnant polarization is desirable for a FE material, such that a large stored charge can be obtained from a small capacitor area, mainly in FeRAM applications. Lead-zirconium titanate Pb[ZrₓTi₁₋ₓ]O₃ (PZT) and related perovskite oxides are the most intensively studied FE materials for FeRAM: their remnant polarization typically ranges from 10-40 μC cm⁻².

Additionally, strontium bismuth tantalate (SBT)—another perovskite oxide FE material—has also attracted extensive interest due to its fatigue-free behavior on Pt electrodes. Nevertheless, the remnant polarization of SBT is small (5-10 μC cm⁻²). Furthermore, perovskite oxides have been difficult to integrate into standard microfabrication processes due to their complex crystal structures and the volatility of Pb and Bi, which poses contamination risks in foundry environments. The discovery of ferroelectricity in aluminum scandium nitride (AlScN)⁷ sparked research in high polarization FE insulators for memory applications. AlScN (and other wurtzite-structured nitrides) exhibit large remnant polarization (75-135 μC cm⁻²). They can also be grown via sputtering at temperatures <400° C. making them compatible with Si complementary metal-oxide-semiconductor (CMOS) transistor fabrication in a back-end-of-line (BEOL) process. Additionally, piezoelectric AlScN is already in widespread commercial usage as filters in radio-frequency communication devices such as cell phones. This suggests that scaling up and integration of AlScN in a foundry process are feasible.

To date, most studies of FE AlScN have been made on films deposited onto elemental metallic substrates. Recently some demonstrations have also been made on conductive ceramics such as TiN and highly doped GaN. Complementing these, silicon carbide (SiC) represents a mature technology with extensive applications in both power electronics and high-temperature electronics. Its added advantage is the close lattice matching with AlScN (˜5.6% lattice mismatch via co-sputtering), which facilitates easy integration over wafer scales. Thus, SiC adds another promising substrate for scalable, wafer-level applications. Additionally, SiC has well-established complementary doping schemes for junction field effect transistors (JFET) and surface conduction channel formation in metal oxide semiconductor (MOS) FET switches making it an ideal platform for AlScN integration. Finally, SiC has emerged as the most prominent wide band-gap semiconductor candidate for a mature high-temperature logic and computing technology, with demonstrations made up to 800° C. This is largely due to its excellent thermal stability, high thermal conductivity, complementary doping, and high carrier mobilities at elevated temperatures. However, high-temperature computing devices noticeably suffer from a lack of non-volatile memory or storage device. A typical silicon-based high-temperature flash memory starts becoming unreliable at <250° C. Therefore there is a strong need for a high-temperature memory compatible with high-temperature SiC logic to enable computing applications in extreme environments. FE AlScN has been recently shown to retain stable ferroelectricity up to 1100° C., and ferroelectric switching under high-temperature of AlScN has been also successfully observed up to 673K without degradation. This fact, combined with the above attributes, makes it imperative to investigate FE AlScN growth and switching behavior on degenerately doped SiC.

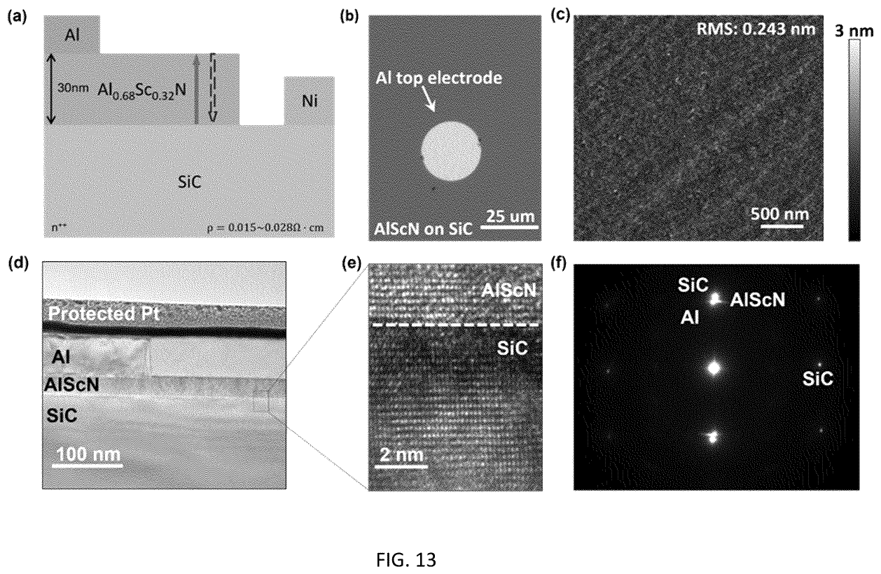

In this disclosure, we demonstrate a non-limiting Al_{0.68}Sc_{0.32}N-based metal-ferroelectric-semiconductor (MFeS) capacitor on SiC and characterize its ferroelectric switching behavior. FIG. 13(a) illustrates the schematic of the MFeS capacitor structure: Nickel/Aluminum is used as the metal electrodes, Al_{0.68}Sc_{0.32}N as the ferroelectric material, and highly doped n-type SiC as the semiconductor. One of the main challenges is that metal/SiC contacts are generally non-ohmic because of the high Schottky barriers up to 1.60-1.70 eV. In addition to employing a highly doped material, the most common way to achieve reliable ohmic contacts in SiC is by using post-annealing techniques after metal deposition, which reduces the barrier height. We have identified nickel (Ni) as the most promising metal to form ohmic contacts to n-type SiC, with annealing temperatures >900° C.

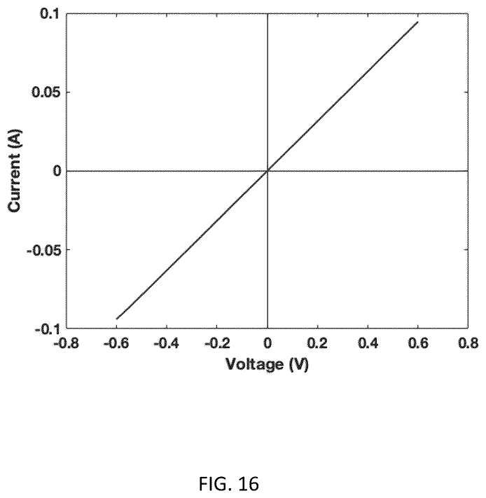

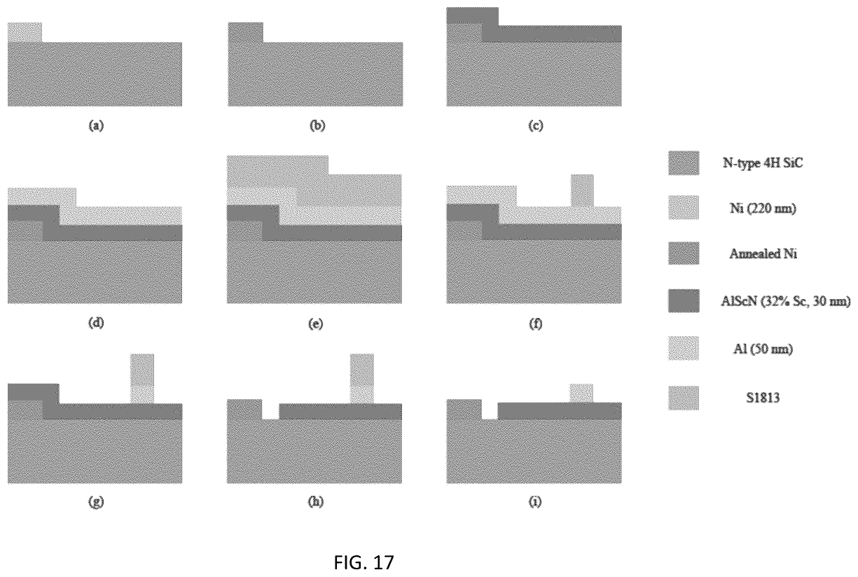

Our sample fabrication starts by depositing and patterning a 220-nm-thick Ni with DC sputtering (Lesker PVD75 DC/RF Sputterer) onto 350-um-thick 4H-SiC wafers (Powerway Wafer Co., Limited, Nitrogen N-type Doped, resistivity of ρ=0.015˜0.028 Ω·cm). The sample was annealed in a furnace for 2 min at 1050° C. with Ar flow under a vacuum atmosphere to form ohmic contacts between the nickel electrode and SiC wafer (see FIG. 16). The 30-nm-thick Al_{0.68}Sc_{0.32}N capacitor layer was then synthesized by sputtering with 150 kHz pulsed DC bias (Evatec Clusterline 200 II) at 350° C. with 20 sccm N₂ flow. The power density for Al target and Sc target were 875 W and 555 W, respectively. A 50-nm-thick capping Al layer as the metal electrode was sputtered on the top of the Al_{0.68}Sc_{0.32}N at 150° C. without breaking the vacuum to prevent surface oxidation of the ferroelectric layer. Circular Al electrodes were patterned via photolithography followed by dry etching in an inductively coupled plasma (ICP) etcher (Oxford PlasmaPro 100 Cobra). Finally, the Ni electrode contact to the SiC was exposed by wet etching the Al_{0.68}Sc_{0.32}N film with 45% KOH solution (see FIG. 17).

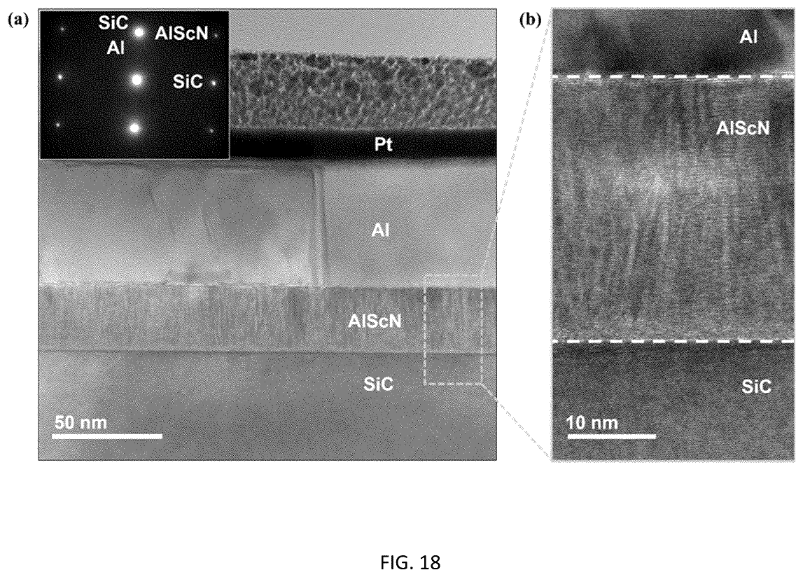

FIG. 13(b) displays a microscopic image of the patterned top Al electrode pad, with a diameter measuring 25 μm. Atomic force microscopy (AFM) was performed for the deposited 30-nm-thick Al_{0.68}Sc_{0.32}N on SiC and an ultra-low surface roughness of 0.243 nm was demonstrated, as shown in FIG. 13(c). We present a cross-sectional transmission electron microscopy (TEM) image of the Al_{0.68}Sc_{0.32}N/SiC interface in FIG. 13(d), along with a magnified image of the interface between the Al_{0.68}Sc_{0.32}N layer and SiC substrate in FIG. 13(e). FIG. 13(f) shows an electron diffraction pattern from the Al electrode, Al_{0.68}Sc_{0.32}N layer, and SiC substrate. The diffraction patterns indicate that the AlScN layer grows with the c-axis broadly parallel to the growth direction and that the film is textured. The interface displays local epitaxial templating of the Al_{0.68}Sc_{0.32}N directly at the SiC interface, which indicates high-quality deposition of the Al_{0.68}Sc_{0.32}N on the SiC substrate (see FIG. 18 for electron microscopy data). The results demonstrate the excellent quality of the interface between the Al_{0.68}Sc_{0.32}N and SiC, which is a factor for the performance and reliability of the device.

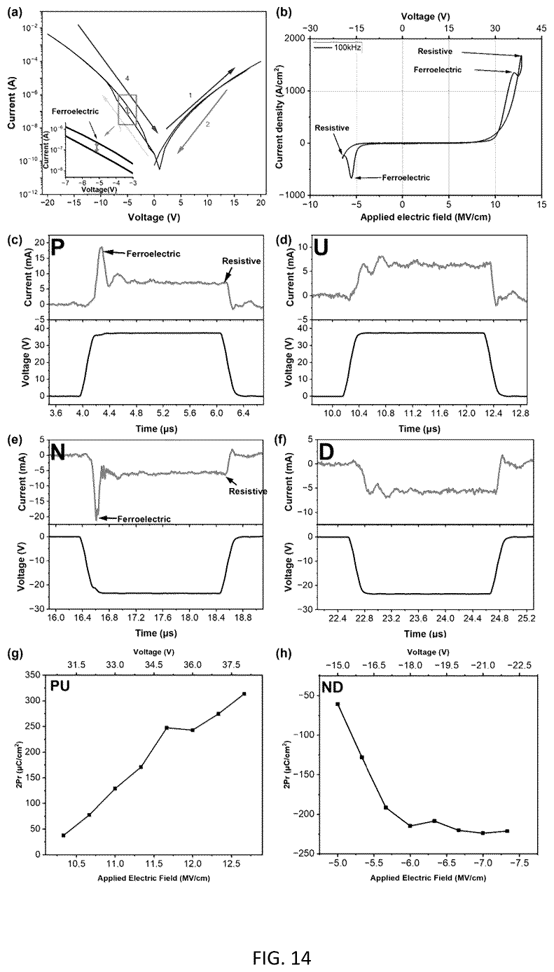

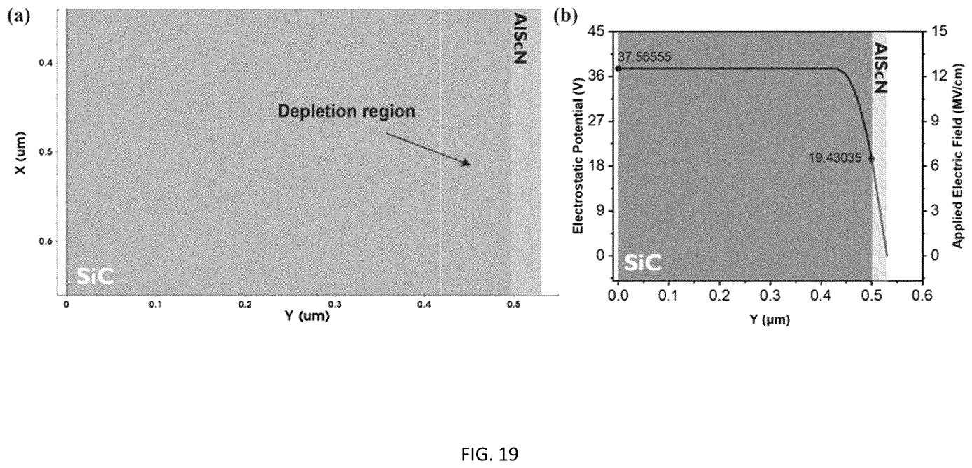

We performed various measurements involving DC, AC, and ultrafast pulsing to characterize the ferroelectric switching of these MFeS capacitors. FIG. 14(a) presents the DC I-V characteristics of the metal/Al_{0.68}Sc_{0.32}N/semiconductor capacitor, sweeping over the range of ±20 V using a semi-log scale. In these measurements, the voltage was applied at the Ni-side electrode while the Al-top electrode was grounded. The device exhibited I-V characteristics similar to a ferroelectric diode. Following the programmed sweep (sweep 2-3), the device's resistance transitioned from high to low (sweep 3 and 4), exhibiting an on-off ratio of 3.19 at −5 V, as depicted in the inset of the FIG. 14(a). Since the MFeS device has an asymmetric structure, the asymmetric voltages are adopted to measure the fabricated capacitor's coercive field (E_{C}) and remnant polarization (Pᵣ). FIG. 14(b) displays the J-E hysteresis curves of the Al_{0.68}Sc_{0.32}N on the SiC under 100 kHz triangular voltage excitation using the same Ni-force/Al-sense measurement configuration. The ferroelectric switching current peaks can be observed for both positive and negative applied voltages. The coercive field was estimated based on the ferroelectric current density peaks in FIG. 14(b), which yields −5.55/+12.05 MV cm⁻¹ at 100 kHz. To explain the asymmetry of the measured coercive field, we propose that the depletion region in the heavily n-type doped SiC substrate divides the voltage when a positive voltage was applied, and the actual voltage (coercive field) that is applied across the Al_{0.68}Sc_{0.32}N layer is much less than +36.15 V (+12.05 MV cm⁻¹). To validate this explanation, we performed TCAD simulations in Synopsys Sentaurus, and estimate that the actual positive E_{C} is +6.48 MV cm⁻¹ (see FIG. 19 for details on simulations and estimates).

Since the J-E measurement applies an asymmetric voltage, a considerable amount of leakage current is observed for positive applied voltages, which hinders accurate estimation of the remanent polarizations (Pᵣ). Therefore, we conducted a PUND measurement with the same Ni-force Al-sense configuration using a 25 μm-diameter top Al electrode, presented in FIG. 14(c)-(f), to determine the remanent polarization of the AlScN layer in the MFeS device. In the PUND measurement, we applied a voltage pulse with a rise/fall time of 100 ns and a pulse width of 2 μs. FIG. 14(c)-(d) shows the current response when applying the “P” and “U” sequences with a positive voltage pulse at +38 V, where the current peak representing ferroelectric switching was observed for the “P” pulse. Similarly, the same ferroelectric switching was observed for the “N” pulse of the “N” and “D” sequences with a negative voltage pulse of −24 V applied, presented in FIG. 14(e)-(f). Since the voltage was divided by the depletion region in the SiC substrate in the “PU” sequence, we adopted an asymmetric PUND measurement to ensure the Al_{0.68}Sc_{0.32}N layer achieves saturable polarization. By integrating the current contributed by ferroelectric and resistive components, we quantitatively estimate the switching polarizations 2Pᵣ by subtracting the polarization measured during the “U” and “D” pulses from that measured during the “P” and “N” pulses as presented in FIG. 14(g)-(h), respectively. The results showed a well-saturated Pᵣ of 110.17 μC cm⁻² for “N-D” sequences at −20 V. Note that in FIG. 14(g), the 2Pᵣ at the “P-U” sequence keeps increasing after reaching saturation polarization at 35 V (˜11.5 MV cm⁻¹) with a remnant polarization Pᵣ of 123.68 μC cm⁻², which is due to uncompensated leakage current caused by the additional applied voltage, the leakage current is also responsible for the overestimated Pᵣ seen in “P-U” sequence.

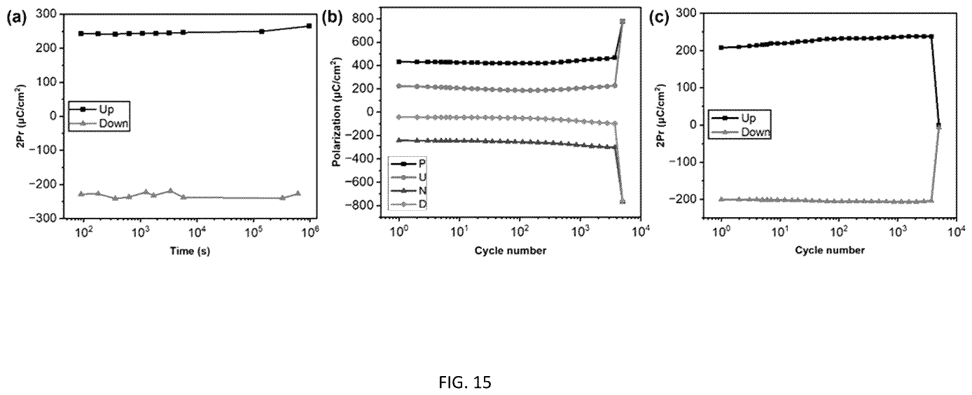

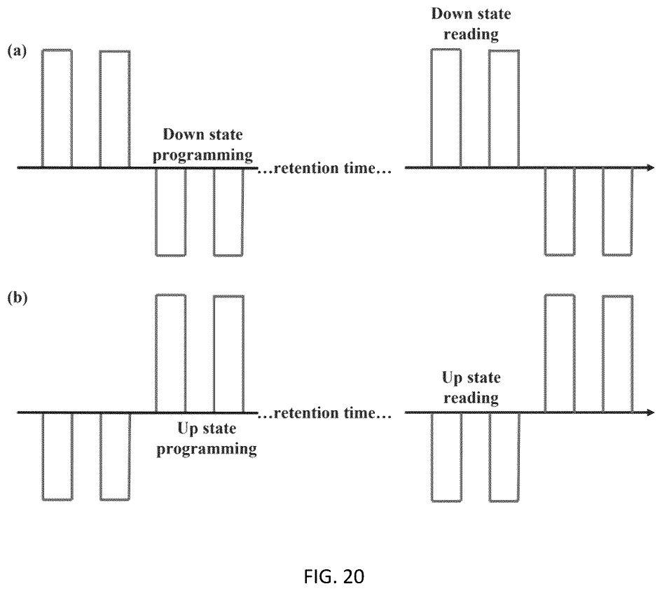

To assess the reliability of the Al_{0.68}Sc_{0.32}N/SiC MFeS ferroelectric capacitors, we perform retention and endurance tests based on asymmetric PUND measurements on the fabricated devices. A pulse setting of −18/+35 V was applied for all four pulse measurements, featuring a pulse width of 2 μs and rise/fall times of 100 ns. The voltages for the pulses were determined by prior PUND measurements, ensuring full polarization in both directions for the device. FIG. 15(a) presents the switching polarizations, 2Pᵣ, for “P-U” (Up) and “N-D” (Down) sequences in a semi-logarithmic scale, with various delay times between two PUND/NDPU measurements (see FIG. 20). The polarization was maintained for at least 10⁶ seconds under ambient room temperature and atmospheric conditions, with no significant depolarization or degradation observed. FIGS. 15(b) and (c) show that the Al_{0.68}Sc_{0.32}N/SiC capacitors could endure 3.7×10³ cycles under −18/+35 V fatigue pulses with a width of 2 μs. The voltage settings for the fatigue pulses were consistent with those in the previously mentioned four-pulse measurements. A slight increase in 2Pᵣ was observed in the “Up” direction.

In summary, we have presented Al/Al_{0.68}Sc_{0.32}N/SiC MFeS ferroelectric capacitors, the key features of which are outlined in Table 4 below. The MFeS capacitor employs a 30-nm-thick AlScN layer deposited directly onto a SiC substrate with low lattice mismatch, resulting in a high coercive field and substantial remnant polarization exhibiting asymmetric characteristics. Furthermore, the reported device demonstrates a retention time exceeding 10⁶ seconds and an endurance of 3.7×10³ cycles. In addition, the DC measurement reveals a current response akin to that of a ferroelectric diode. The results underscore the utility of thin FE AlScN directly grown on SiC wafers for ferroelectric non-volatile memory applications.

TABLE 4
Summary of the ferroelectricity of the reported
MFS (Al/Al_{0.68}Sc_{0.32}N/SiC) capacitor.

| | |
|---|---|
| MFS Capacitor | Al/Al_{0.68}Sc_{0.32}N(30 nm)/SiC |
| DC, on-off ratio | 3.19 (@ −5 V) |
| Coercive field (E_{C}) | −5.55/+12.05 (100 kHz, |
| [MV cm⁻¹] | with voltage divided by the depletion |
| | region in SiC substrate) |
| | −5.55/+6.48 (100 kHz, |
| | without voltage divided by the depletion |
| | region in SiC substrate) |
| Remnant polarization (Pᵣ) | 110.17 |
| [μC cm⁻²] | |
| Retention [s] | >10⁶ |
| Endurance [cycle number] | 3.7 × 10³ |

### Lattice Mismatch AlScN/SiC

The expected lattice constants for Al₁₋ₓScₓN as a function of Sc-fraction x are¹

$${a}_{0} ( x ) = {a}_{A l N} ( 1 + 0.1263 x + 0.0740 {x}^{2} )$$

$${c}_{0} ( x ) = {c}_{A l N} ( 1 + 0.0309 x + 0.1697 {x}^{2} - 0.556 {x}^{3} )$$

where the a_{AlN} and c_{AlN} are the unstrained lattice constants for pure AlN.

With the unstrained reference values of AlN 3.11131 Å and 4.98079 Å, ²the expected lattice constants for Al_{0.68}Sc_{0.32}N are a₀(0.32)=3.2513 Å and c₀(0.32)=5.0081 Å.

The lattice constants for 4H—SiC structures are a_{SiC}=3.079 Å and c_{SiC}=10.07 Å.³

Using the above data, the lattice mismatch of Al_{0.68}Sc_{0.32}N and 4H—SiC is

$$Lattice mismatch = \frac{{a}_{S i C} - {a}_{0} ( 0.32 )}{{a}_{S i C}} = 5 \text{.60} \&$$

As described herein, the disclosure MIM devices can operate at voltages that are within the range of SiC transistors. Accordingly, the disclosed MIM devices can operate in sync with SiC processors reliably at high temperatures. SiC processors are the only known technology that can operate up to high temperatures reliably but currently do not have non-volatile memory to perform complex computation. Thus, the disclosed MIM devices that can be stable at those temperatures and work in the same voltage range as SiC transistors is a significant step forward towards complex memory augmented computer processors operating at elevated temperatures; the disclosed technology (which can include combining a MIM device with a SiC device) allows one to perform complex calculations and data processing at elevated temperatures at which such operations are currently impossible. Further, the disclosed technology improves the power efficiency of the entire system.

### Additional Disclosure

The development of high-temperature and radiation-resistant non-volatile memory is critical for advanced computing hardware operating in extreme environments such as in nuclear power and in spacecrafts. Ferroelectric Aluminum Scandium Nitride (Al1-xScxN) exhibits strong potential for utilization in non-volatile memory (NVM) devices operating under large gamma radiation and at extreme temperatures given its sizeable remnant polarization above 100 μC/cm² and demonstrated ferroelectric transition temperature over 1000° C. In this work, we demonstrate an Al_{0.68}Sc_{0.32}N based ferroelectric NVM that reliably operates with distinct ferroelectric ON and OFF states, which are maintained even after exposure to 106 rad (1 Mrad) gamma radiation. This in conjunction with our prior work on stable 600° C. operation of Al_{0.68}Sc_{0.32}N based ferroelectric NVM marks a significant step toward both temperature and radiation-hard NVM technology.

### INTRODUCTION

Traditional Silicon (Si)-based micro(nano)electronics, encountered in complementary metal oxide semiconductor (CMOS) technology, face reliability challenges above 200° C. The number of thermally induced carriers exceeds the doping concentration level, which damages their functional properties. This becomes a significant challenge as emerging harsh environment applications, including aerospace, space exploration and nuclear plants, require complex computing and sensing capabilities in-situ. Extensive research has led to the development of now well-established wide bandgap semiconductor material solutions such as Silicon Carbide (SiC) for logic transistors, which can effectively operate at temperatures as high as 800° C. However, the absence of non-volatile memory (NVM) devices suitable for information storage hinders the execution of intricate computing operations at elevated temperatures.

Further, space exploration involves exposure to gamma radiation produced by the hottest and most energetic objects in the universe, such as neutron stars and regions around black holes. These rays can cause data corruption in NVM devices, leading to system failures. The development of specialized NVM solutions is therefore necessary. In particular, NVM solutions that are resistant to both high temperature and high energy radiation are currently unavailable. Ferroelectric materials are well-suited for low-power NVM applications as they exhibit fast switching speed, low switching energy, long retention, and have potential for multibit operation. To meet the demands of harsh environment applications such as extreme temperature and exposure to radiation, ferroelectric materials also need high Curie temperatures (TC) and remnant polarizations (P_{R}). Wurtzite structured III-Nitride based ferroelectric Aluminum Scandium Nitride (Al₁₋ₓScₓN) concurrently exhibits high P_{R}>100 μC/cm², large coercive field (E_{C})>2 MV/cm, and a very high ferroelectric transition temperature T_{C}>1000° C.

Here, we demonstrate Al₁₋ₓScₓN ferroelectric diode-based NVM devices that can operate at up to 600° C. at ≤20 V and under 1 Mrad Cobalt-60 (⁶⁰Co) gamma radiation, ensuring hardness against both high temperature and gamma radiation.

### Device Structure

In this study, we fabricated metal-ferroelectric-metal (MFM) structures of Au/Ti/Al_{0.64}Sc_{0.36}N (50 nm)/Pt (111) grown on 4″ Silicon wafers. These structures can be used as both ferroelectric diode type resistive memory devices as well as ferroelectric capacitors. An optical microscope image of such devices of different lateral dimensions is shown in FIG. 24(a). Gold is used as a top contact for gamma radiation shielding associated to its high material density. Furthermore, we demonstrate similarly assembled Ni/Al_{0.68}Sc_{0.32}N (45 nm)/Pt (111) MFM devices that can operate at up to 600° C. The 50 nm and 45 nm films are calibrated to meet the voltage requirements for SiC electronics while striking a balance of other relevant properties, such as remnant polarization, ON-OFF resistance ratio, and leakage current.

### Preliminary Measurements

To investigate the impact of radiation on ferroelectric diode characteristics, ferroelectric switching, and leakage current behavior, quasi-DC (0.01 Hz) I-V hysteresis measurements were performed on pristine MFM Al_{0.64}Sc_{0.36}N structures with 25 μm radii. Ferroelectric behavior can be clearly observed in the devices from the change in the resistance upon ferroelectric switching (FIG. 24(b)). To set a device in the high resistance state (HRS), the applied voltage is first swept to the maximum value in the range (23V in FIG. 24(b)), and then down until the minimum value (−23V in FIG. 24(b)), in decreasing voltage steps before being driven back to 0V. To set a device in the low resistance state (LRS), the voltage is cycled in the opposite direction: the voltage starts off being swept from 0V to −23V and ends by being decreased from 23V back to 0V. Positive-Up Negative-Down (PUND) measurements were also performed on pristine devices: two pairs of identical voltage pulses (positive and negative) are applied to the device. Switching and non-switching currents are generated by the first pulse, whereas the second produces only non-switching current such as leakage.

By switching the devices from nitrogen (N)-polar to metal (M)-polar states and back, then measuring the difference between switching and non-switching currents, PUND measurement offers a time-resolved approach to probe the signature of ferroelectricity and to explore the polarization dynamics of Al₁₋ₓScₓN devices. As PUND measurements set the devices to the N-polar state with pulses of duration 1×10⁻⁶ s each and 5×10⁻⁶ s delay between each pulse, similar Positive-Up (PU) pulses fixed other pristine devices to M-polar.

Finally, the PUND and PU voltage schemes were repeated for a separate set of devices with triangle waves of 400 μs duration for a single triangle and |dV/dt|=˜150 kV/s each. This latter measurement cyclically recreates the hysteresis poling of quasi-DC measurements.

### Results and Discussion

### Radiation Effects

Following these preliminary measurements, we exposed the 50 nm Al_{0.64}Sc_{0.36}N devices to 1 Mrad gamma radiation. This is done using ⁶⁰Co, a synthetic radioactive emitter of high-intensity gamma rays. Two months later, the retention of the devices' polar states was confirmed with the application of identical PUND or PU pulses as in the preliminary measurements at room temperature (RT, ˜25° C.).

Applying a PU pulse to a previously M-polar device results in no switching, which indicates that the device is still in the state it was initially set to (FIG. 25(a)). Similarly, applying an ND pulse to a previously N-polar device results in no switching (FIG. 24(b)). These measurements demonstrate same-state retention after radiation. In addition to maintaining their state, the devices are still able to switch, as shown in FIG. 25(c), where applying an ND pulse to a previously M-polar device results in successful switching. This demonstrates opposite state retention after radiation exposure. Second PUND measurements also confirm that the device is still able to switch in both directions at the voltages used in the preliminary step (FIG. 24(c)). By maintaining their polarization, the devices are a reliable NVM that keep their memory state unaffected by radiation. We also investigate the effect of radiation on the Al_{0.64}Sc_{0.36}N ferroelectric signature by repeating the quasi-DC I-V and triangular PUND measurements on the devices. The change in P_{R} is minimal, as reported in FIG. 26 and FIG. 27(a,b).

The LRS devices ON-OFF ratio decreased before and after irradiation from 4.61 (±1.27) to 3.26 (±0.71) respectively for a 5V read voltage. In the case of HRS devices, the ON-OFF ratio increased from 4.24 (±0.75) to 6.95 (±1.04) respectively. In triangle wave PUND measurements, the difference between switching and non-switching polarization peaks also increases after irradiation, which indicates an improved ferroelectric signal. In agreement with FIG. 25(a), applying a triangle wave PU pulse to a previously M-polar device results in no switching (FIG. 27(c)). Out of 40 poled devices (10 square PUND, 10 square PU, 10 triangle wave PUND, 10 triangle wave PU), all had retained their states and switching properties post-irradiation. Out of the additional 20 quasi-DC I-V devices, only one shorted during the second round of measurements and all others retained their states.

In a resistive memory circuit, the difference between LRS and HRS is used to differentiate two-bit states as “1” and “0,” respectively. While capacitors can break down over cycling at the large fields required for writing, for a ferroelectric diode, read operations can be achieved at low voltages that do not induce failure. To properly distinguish the device state, an applied voltage on LRS devices must consistently return a smaller average resistance than HRS. Our devices showed this behavior before and after irradiation (FIG. 28), indicating that the bit state was preserved, and that the device can still be used as a NVM. The average current density is 8.40 mA/cm² and 7.99 mA/cm² for LRS devices and 2.02 mA/cm² and 1.51 mA/cm² for HRS devices, pre- and post-radiation respectively.

### Temperature Effects

To investigate the impact of temperature on our 45 nm thick Al_{0.68}Sc_{0.32}N diodes, quasi-DC I-V hysteresis measurements were performed across a temperature range from RT to 600° C. in 100° C. increments, skipping 100° C. and 200° C. (FIG. 29(a)). Ferroelectric diode-like behavior is clearly maintained up to 600° C. The E_{C+} values at RT and 600° C. were found to be 3.16 and 2.05 (+/−0.1) MV/cm, respectively. The E_{C-} values at RT and at 500° C. were observed to be −2.94 and −1.88 (+/−0.1) MV/cm, respectively. The devices also exhibited an ON-OFF ratio of 8.50 (±0.40) at RT and 1.99 (±0.23) at 600° C. for a 5V read voltage. Similarly, triangle wave I-V measurements exhibit a linear reduction with respect to temperature.

These measurements demonstrate that ferroelectric switching is maintained up to 600° C. for both positive and negative voltage pulses. Reads taken at 5V yield a current density of 6-11 mA/cm² in devices with 50 μm radius, depending on the polarization state. The evolution of these currents over read cycles and time is shown in FIG. 29(b) at 600° C. Over 10⁶ cycles of 100 μs, each were successfully read over the course of approximately two minutes. A decrease in the ON-state current within the first 2×10⁴ cycles is followed by a slight continuous decrease in both ON and OFF-state current density. Differential retention tests of 6-hour and 60-hour duration at 600° C. were performed, where the difference between the measured current density of Metal-polar (HRS) and Nitrogen-polar (LRS) ferroelectric capacitors are plotted in FIG. 29(c). The ON-state current continues to drop throughout the test, reducing the ON-OFF ratio to 1.99 by 6 hours and 1.83 by the end of 60 hours. Write endurance tests were performed in groups of 100 write pulses, followed by a triangle wave I-V test to determine the device status and if any changes in device properties are visible. At 600° C., devices survived for 868±130 cycles at 19 V write voltage.

### CONCLUSION

We have demonstrated ferroelectric Al_{0.64}Sc_{0.36}N based NVM devices with an MFM structure that survived ⁶⁰Co gamma radiation up to 1 Mrad without changing their polarization states. Quasi-DC I-V, PUND, PU, triangle wave PUND, and triangle wave PU measurements confirmed that the devices were still operational, and their ferroelectric signature minimally altered; such devices—including Al_{0.68}Sc_{0.32}N devices—were shown to stably operate up to 600° C. The ferroelectric properties and memory device characteristics were evaluated using quasi-DC, AC and Triangle Wave IV measurements.

### ASPECTS

The following Aspects are illustrative only and do not limit the scope of the present disclosure or the appended claims. Any part or parts of any one or more Aspects can be combined with any part or parts of any one or more other Aspects.

Aspect 1. A ferroelectric non-volatile memory component, comprising: a first electrode comprising a first metal; a ferroelectric portion; and a second electrode comprising a second metal; the ferroelectric portion placing the first electrode and the second electrode into electronic communication with one another, the ferroelectric portion optionally contacting at least one of the first electrode and the second electrode, the ferroelectric portion comprising AlₓSc₍₁₋ₓ₎N, the component optionally comprising a non-ferroelectric interlayer disposed between the ferroelectric portion and the first electrode and/or between the ferroelectric portion and the second electrode, and the component optionally exhibiting at least one of (a) an operating voltage of less than 15 V at 600° C., (b) an on/off ratio of greater than 1 at a temperature of 600° C., and (c) retention of a polar state following exposure to 1 Mrad Cobalt-60 (⁶⁰Co) gamma radiation.

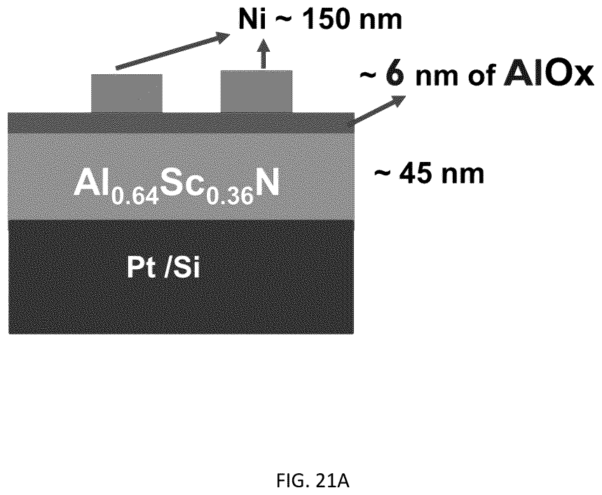

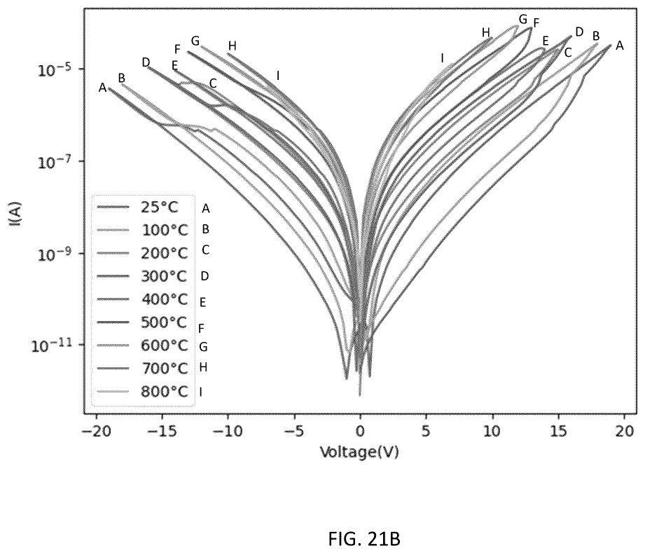

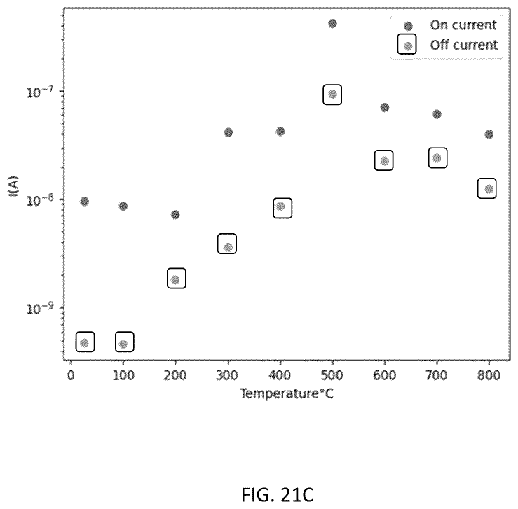

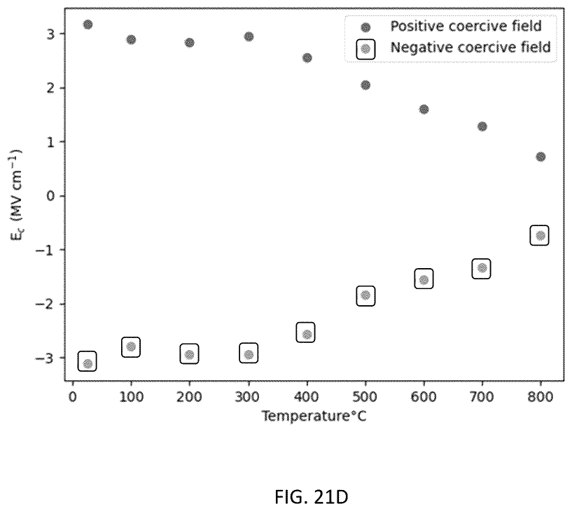

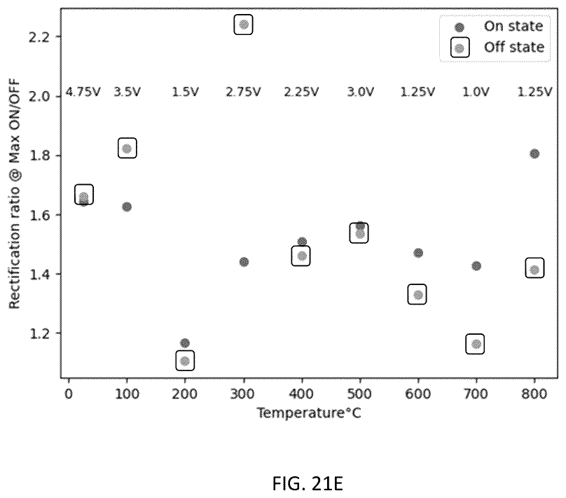

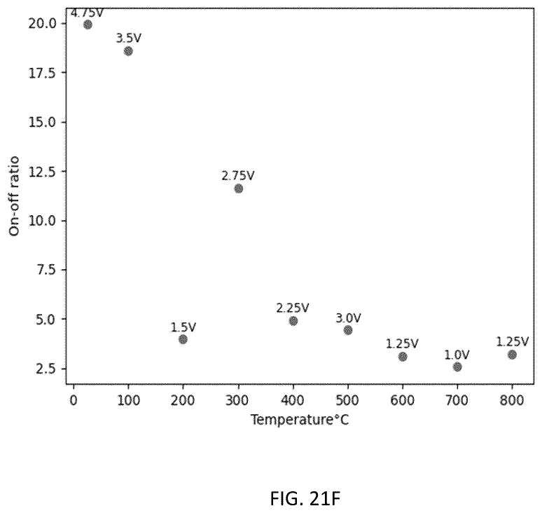

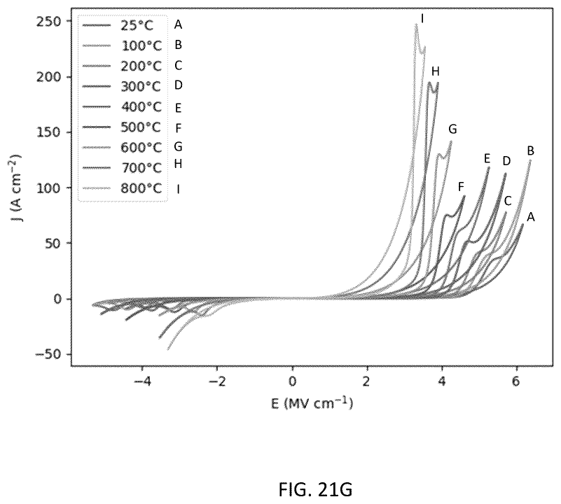

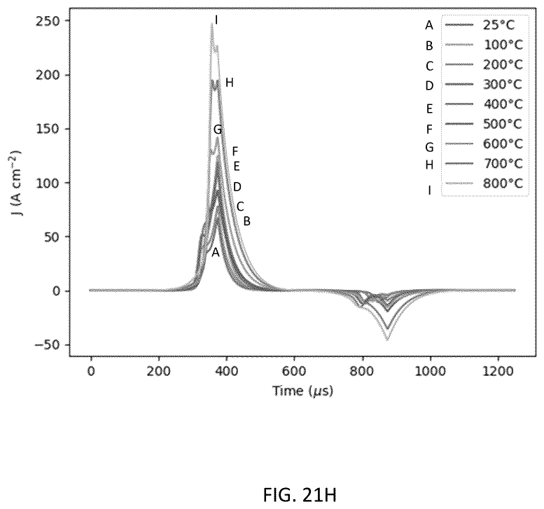

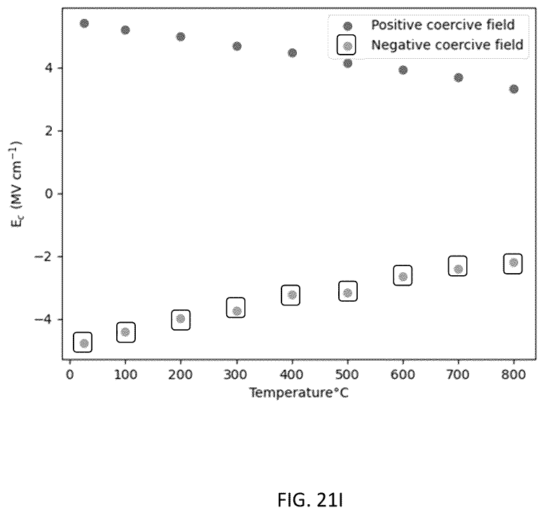

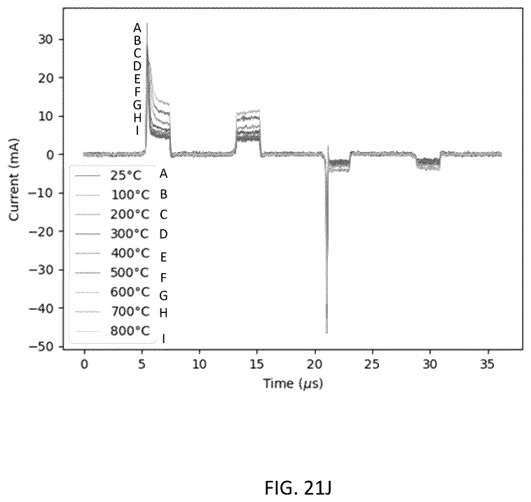

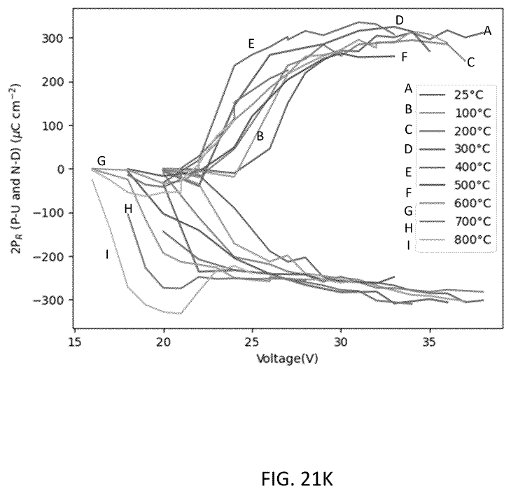

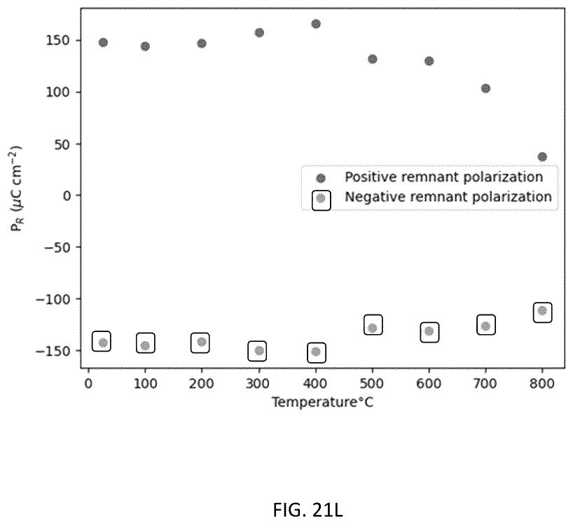

In some embodiments, the component exhibits an on/off ratio of from about 2 to about 200, optionally from greater than 1 to about 200, or even optionally from about 10 to about 150, at a temperature of 600° C. The on/off ratio can be, for example, from greater than 1 to about 5, from greater than 1 to about 4, from greater than 1 to about 3, or even from greater than 1 to about 2. Exemplary, non-limiting on/off data are provided in FIGS. 21F and 22F.

As described, a component can include an interlayer disposed between (i) the first electrode and the ferroelectric portion or (ii) between the ferroelectric portion and the second electrode. The interlayer can comprise a non-ferroelectric material. As non-limiting examples, an interlayer can include any one or more of YOx, ZrOx, LaOx, NiOx, HfSiOx, ZrSiOx, TiOx, AlOx, HfOx, MgOx, SiOx, TaOx, and SiNx; other amorphous insulating oxides and nitrides can also be comprised in the interlayer. An interlayer can have a thickness of from about 0.5 nm to about 50 nm, in some embodiments. An interlayer can have a thickness of, for example, from about 1 nm to about 50 nm, from about 1 nm to about 40 nm, from about 1 nm to about 30 nm, from about 1 nm to about 20 nm, or even from about 1 nm to about 10 nm.

Without being bound to any particular theory or embodiment, the presence of an interlayer can enhance the component's ON/OFF ratio at comparatively elevated temperatures. As but some examples, ON/OFF ratios of greater than 25 and rectification ratios of greater than 25 are observed for temperatures as high as 800° C. in an example device having a 10 nm thick AlOx interlayer; ON/OFF ratios of greater than 200 and rectification ratios greater than 200 are observed for temperatures as high as 700° C. for 10 nm thick AlOx interlayer. Ec is observed to reduce with increasing temperature, and no significant change was observed in Pᵣ with temperature. When present, the interlayer can be disposed between the ferroelectric portion and the first electrode.

Aspect 2. The component of Aspect 1, wherein the first electrode comprises any one or more of Al, Ni, Mo, W, Pt, Ti, Au, TiN, HfN, ZrN, Hf, Zr, Nb, Ta, Cu, and alloys thereof. Ni and Au are considered particularly suitable for use in the first electrode. Au can be present as a contact; Au can also be present in the first electrode.

Transition metals can be used as first electrodes. The thickness of the first electrode can vary depending on the user's needs. As a non-limiting example, a first electrode can have a thickness in the range of from about 10 to about 1000 nm, such as from about 20 to about 200 nm. Au can be present as, for example, a top contact.

Aspect 3. The component of any one of Aspects 1-2, wherein the second electrode comprises Pt. The second electrode can, for example, comprise Pt (111)/Ti/SiO₂ on a Si substrate. The second electrode can comprise any one or more of Al (111), Ti (002), TiN (111), HfN (111), ZrN (111), NbN (111), Sc (002), Hf (002), Zr(002), Mo (110), W(110), Nb (110), Ta (110), SiC (002), ScN (111), Y (002), and GaN (002). Pt and SiC are considered particularly suitable for inclusion in the second electrode.

Aspect 4. The component of any one of Aspects 1-3, wherein x=0.01 to 0.8, optionally wherein x=from 0.64 to 0.68. In some embodiments, x can be from about 0.3 to about 0.7.

Without being bound to any particular theory or embodiment, a value of x=0.68 is considered particularly suitable, particularly for components that comprise Al_{0.68}Sc_{0.32}N. X can be, for example, from about 0.25 to about 0.75, from about 0.26 to about 0.74, from about 0.27 to about 0.73, from about 0.28 to about 0.72, from about 0.29 to about 0.71, from about 0.30 to about 0.70, from about 0.31 to about 0.69, from about 0.32 to about 0.68, from about 0.33 to about 0.67, from about 0.34 to about 0.66, from about 0.35 to about 0.65, from about 0.36 to about 0.64, from about 0.37 to about 0.63, from about 0.38 to about 0.62, from about 0.39 to about 0.61, from about 0.40 to about 0.60, from about 0.41 to about 0.59, from about 0.42 to about 0.58, from about 0.43 to about 0.57, from about 0.44 to about 0.56, from about 0.45 to about 0.55, from about 0.46 to about 0.54, from about 0.47 to about 0.53, from about 0.48 to about 0.52, from about 0.49 to about 0.51, or even about 0.5. X values of 0.63 to 0.69 are considered especially suitable.

Aspect 5. The component of any one of Aspects 1-4, wherein the component is supported by a substrate that comprises any one or more of silicon, silicon carbide (including 4H and 6H structure), GaN, sapphire, quartz, aluminum nitride, and fused silica.

Aspect 6. The component of Aspect 5, wherein the substrate comprises any one or more of silicon carbide, sapphire, aluminum nitride, or quartz.

Aspect 7. The component of any one of Aspects 1-6, wherein the component exhibits an operating voltage of less than 15 V at 600° C. Such a voltage can be, for example, less than 15 V, less than 14 V, less than 13 V, less than 12 V, less than 11 V, less than 10 V, less than 9 V, less than 8 V, less than 7 V, less than 6 V, less than 5 V, less than 4 V, less than 3 V, less than 2 V, and even less than 1 V.

Aspect 8. The component of any one of Aspects 1-6, wherein the component exhibits an on/off ratio of greater than 1 at a temperature from 200 to 800° C., the component optionally exhibiting an on/off ratio of about 8 at room temperature. In some embodiments, the component exhibits an ON/OFF ratio of from about 2 to about 250 at a temperature between 0° C. and 800° C. In some embodiments, the component exhibits an ON/OFF ratio of from about 2 to about 100 at a temperature between 0° C. and 800° C. The component can exhibit an ON/OFF ratio at a temperature between 0° C. and 800° C. of from about 2 to about 250, from about 2 to about 200, from about 2 to about 100, from about 2 to about 75, from about 2 to about 50, from about 3 to about 40, from about 4 to about 30, or from about 5 to about 25. The ON/OFF ratio can be from greater than 1 to about 5 at a temperature between 100° C. and 800° C.

Illustrative, non-limiting data are provided in FIGS. 2-4, attached hereto. A device according to the present disclosure can, for example, exhibit an on/off ratio of up to about 20 at room temperature. A device according to the present disclosure can exhibit an on/off ratio of from 1.1 up to, for example, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 5.0, 10.0, 20.0, 50.0, 60.0, 70.0, or even 80.0 at 500° C. or even at 600° C. A device according to the present disclosure can exhibit an on/off ratio of from 1.1 up to, for example, 1.2, 1.3, 1.4, 1.5, 1.6, 1.7, 1.8, 1.9, or even about 70 at 500° C.

In some embodiments, an ON/OFF ratio for the component is greater than 3 over a 1,000 s time period when the non-ferroelectric interlayer has a thickness of approximately 1 nm. The ON/OFF ratio can be from greater than 3 up to about 1000, from greater than 3 up to about 500, from greater than 3 up to about 100, from greater than 3 up to about 50, or even from greater than 3 up to about 10.

In some embodiments, an ON/OFF ratio for the component is greater than 9 over a 1,000 s time period when the non-ferroelectric interlayer has a thickness of approximately 2 nm. The ON/OFF ratio can be from greater than 9 up to about 1000, from greater than 9 up to about 500, from greater than 9 up to about 100, from greater than 9 up to about 50, or even from greater than 9 up to about 10.

In some embodiments, an ON/OFF ratio for the ferroelectric diode is greater than 3 over a 1,000 s time period, for example when the non-ferroelectric interlayer has a thickness of approximately 3 nm. The ON/OFF ratio can be from greater than 3 up to about 1000, from greater than 3 up to about 500, from greater than 3 up to about 100, from greater than 3 up to about 50, or even from greater than 3 up to about 10. In some embodiments, an ON/OFF ratio for the component diode is greater than 100 over a 1,000 s time period when the non-ferroelectric interlayer has a thickness of approximately 4 nm. The ON/OFF ratio can be from greater than 100 up to about 1000, from greater than 100 up to about 500, from greater than 100 up to about 200, or even from greater than 100 up to about 150. In some embodiments, an ON/OFF ratio for the ferroelectric diode is greater than 150 over a 1,000 s time period when the non-ferroelectric interlayer has a thickness of approximately 5 nm. The ON/OFF ratio can be from greater than 150 up to about 1000, from greater than 150 up to about 500, from greater than 150 up to about 200, or even from greater than 150 up to about 175. In some embodiments, the ferroelectric diode can be configured with at least 32 multi-states having an ON/OFF ratio of greater than 1,100 over a 300 s time period.

A device according to the present disclosure can, for example, perform 10⁶ read cycles at 500 C; exemplary existing devices perform fewer than 10,000 read cycles at 380° C. Accordingly, the disclosed devices provide greater read cycle performance than existing devices, and the disclosed devices do so at higher temperatures than existing devices.

A component according to the present disclosure can retain a polar state—such as (N)-polar or (M)-polar—following exposure to 1 Mrad Cobalt-60 (⁶⁰Co) gamma radiation. Such exposure can be, for example, for 1 day, for 10 days, for 15 days, for 20 days, for 30 days, for 40 days, for 50 days, or even for 60 days. Polar state retention can be assessed by, for example, application of identical PU or PUND pulses that used to collect preliminary measurements of a component at room temperature before exposure to the gamma radiation. Without being bound to any particular theory or embodiment, the disclosed devices can be used as NVM in environments—such as in space—where gamma radiation is present.

Aspect 9. The component of any one of Aspects 1-8, wherein the component exhibits any one or more of (1) coercive electric field at 100 kHz from −2.5 to −5 (e.g., −2.94 to −5.83) MV/cm for the negative field direction at room temperature and +3 to about +6.5 (e.g., +3.16 to +5.98) MV/cm for the positive field direction at room temperature, (2) a positive remnant polarization at room temperature of about 120.5 μC/cm2 and a negative remnant polarization at room temperature of about −128.0 μC/cm²; (3) read cycling of about 10⁶ cycles at room temperature and at about 500° C.; (4) a retention time of at least 6 hours at room temperature and at about 500° C.; (5) a write endurance of about 6000 cycles at room temperature; and (6) a write endurance of about 1400 cycles at 500° C. A component according to the present disclosure can have a switching voltage of less than 15 V or even less than 13 V.

Aspect 10. The component of any one of Aspects 1-9, wherein the ferroelectric portion defines a height in the range of 10 to about 100 nm. The ferroelectric portion can have a height of less than 20 nm, in some embodiments.

Aspect 11. The component according to any one of Aspects 1-10, wherein the component is in electronic communication with a processor. Such a processor can be comprised, for example, in a mobile device, although this is not a requirement.

Aspect 12. The component of Aspect 11, wherein the component is wirebonded to the processor.

Aspect 13. A method, comprising operating a component according to any one of Aspects 1-12.

Aspect 14. A method, comprising applying a voltage to a component according to any one of Aspects 1-12 so as to convert the component between a first persistent electronic polarization and conduction state and a second persistent electronic polarization and conduction state.

Aspect 15. A computing device, the computing device comprising a component according to any one of Aspects 1-12.

Aspect 16. A ferroelectric capacitor, comprising: a first electrode comprising a first metal; a ferroelectric portion, the ferroelectric portion comprising AlₓSc₍₁₋ₓ₎N; a second electrode comprising a second metal; and a silicon carbide portion; the ferroelectric portion contacting the first electrode and the silicon carbide portion, the second electrode contacting the silicon carbide portion. An example such device is provided in FIG. 13(a).

Without being bound to any particular theory or embodiment, capacitors according to the present disclosure exhibit stable and robust ferroelectric switching to 900° C. Ec was observed to reduce with increasing temperature, and no significant change in Pᵣ was seen with temperature. Write cycling endurance was observed to decrease with increasing temperature; state retention observed up to 100 hours for 600° C. with no observable change/degradation and measured up to 10,000 seconds at 800° C. with no observable change/degradation. A capacitor according to the present disclosure can retain a polar state following exposure to 1 Mrad Cobalt-60 (⁶⁰Co) gamma radiation.

Aspect 17. The capacitor of Aspect 16, wherein the first electrode comprises any one or more of Al, Pt, Pd, Mo, Ti, Ni, W, Ta, and Au. The first electrode can, in some embodiments, comprise one or more transition metals.

Aspect 18. The capacitor of any one of Aspects 16-17, wherein the second electrode comprises any one or more of Pt, Pd, Mo, Ti, Ni, Al, W, Ta, and Au. The second electrode can, in some embodiments, comprise one or more transition metals.

Aspect 19. The capacitor of any one of Aspects 16-18, wherein x=0.1 to 0.8, for example from 0.4 to 0.8, or even from 0.5 to 0.7. X can be, for example, from 0.6 to 0.8; x values from 0.64 to 0.68 are considered especially suitable.

Aspect 20. The capacitor of any one of Aspects 16-19, wherein the substrate comprises 4H or 6H silicon carbide. The foregoing types of SiC are non-limiting, as the disclosed technology can be used with essentially any form of SiC.

Aspect 21. The capacitor of any one of Aspects 16-20, wherein the capacitor exhibits any one or more of (1) coercive electric field ranges at 100 kHz from −5.5 to −6.8 MV/cm for the negative field direction and from +9.8 to +12.0 MV/cm for the positive field direction, (2) a saturated remnant polarization range from 110 to 130 μC/cm², (3) an endurance of up to 3700 cycles, and (4) a retention time of up to 9.5×10⁵ seconds for both N-polar and metal-polar states.

Aspect 22. The capacitor of any one of Aspects 16-21, wherein the ferroelectric portion defines a height in the range of about 5 to about 50 nm, optionally from about 10 to about 45 nm.

Aspect 23. The capacitor according to any one of Aspects 16-22, wherein the component is in electronic communication with a processor.

Aspect 24. The capacitor of Aspect 23, wherein the capacitor is wirebonded to the processor.

Aspect 25. A method, comprising operating a capacitor according to any one of Aspects 16-24.

Aspect 26. A method, comprising applying a voltage to a component according to any one of Aspects 16-24 so as to convert the component between a first persistent electronic polarization and conduction state and a second electronic polarization and conduction persistent state.

Aspect 27. A ferroelectric component, comprising: a ferroelectric portion, the ferroelectric portion comprising AlₓSc₍₁₋ₓ₎N; a first electrode comprising a first metal, the first electrode surmounting at least a portion of the ferroelectric portion; and a second electrode comprising a second metal. The component can, in some embodiments, comprise an interlayer disposed between the first electrode and the ferroelectric portion. Suitable interlayers are described elsewhere herein.

Aspect 28. The component of Aspect 27, wherein the ferroelectric portion surmounts the second electrode.

Aspect 29. The component of any one of Aspects 27-28, further comprising a silicon carbide support, the ferroelectric portion surmounting at least a portion of the silicon carbide support and the second electrode surmounting at least a portion of the silicon carbide support.

Aspect 30. The component of any one of Aspects 27-29, wherein x is from about 0.6 to about 0.8.

Aspect 31. The component of any one of Aspects 27-30, wherein the ferroelectric portion defines a height of from about 10 to about 100 nm.

Aspect 32. The component of any one of Aspects 27-31, wherein the first electrode comprises any one or more of Al, Au, Ti, Cr, and Ni. The first electrode can comprise one or more transition metals.

Aspect 33. The component of any one of Aspects 27-32, wherein the second electrode comprises any one or more of Ni and Pt.

Aspect 34. The component according to any one of Aspects 27-33, wherein the component is in electronic communication with a processor.

Aspect 35. The capacitor of Aspect 34, wherein the capacitor is wirebonded to the processor.

Aspect 36. A method, comprising operating a capacitor according to any one of Aspects 27-34.

Aspect 37. A method, comprising applying a voltage to a component according to any one of Aspects 27-34 so as to convert the component between a first persistent electronic polarization and conduction state and a second persistent electronic polarization and conduction state.

What is claimed:

1. A ferroelectric non-volatile memory component, comprising:
a first electrode comprising a first metal;
a ferroelectric portion; and
a second electrode comprising a second metal;
the ferroelectric portion placing the first electrode and the second electrode into electronic communication with one another,
the ferroelectric portion optionally contacting at least one of the first electrode and the second electrode,
the ferroelectric portion comprising AlₓSc₍₁₋ₓ₎N,
the component optionally comprising a non-ferroelectric interlayer disposed between the ferroelectric portion and the first electrode and/or between the ferroelectric portion and the second electrode, and
the component optionally exhibiting at least one of (a) an operating voltage of less than 15 V at 600° C., (b) an on/off ratio of greater than 1 at a temperature of 600° C., and (c) retention of a polar state following exposure to 1 Mrad Cobalt-60 (⁶⁰Co) gamma radiation.

2. The component of claim 1, wherein the first electrode comprises any one or more of Al, Ni, Mo, W, Pt, Ti, Au, TiN, and alloys thereof.

3. The component of claim 1, wherein the second electrode comprises Pt, the second electrode optionally comprising Pt (111)/Ti/SiO₂ on Si substrate.

4. The component of claim 1, wherein x=0.01 to 0.8, optionally wherein x=0.64 to 0.68.

5. The component of claim 1, wherein the component is supported by a substrate that comprises any one or more of silicon, 4H silicon carbide, 6H silicon carbide, GaN, sapphire, quartz, aluminum nitride, and fused silica.

6. The component of claim 1, wherein the component exhibits an operating voltage of less than 15 V at 600° C.

7. The component of claim 1, wherein the component exhibits an on/off ratio of greater than 1 at a temperature from 200 to 800° C., the component optionally exhibiting an on/off ratio of about 8 at room temperature.

8. The component of claim 1, wherein the component exhibits any one or more of (1) coercive electric field at 100 kHz from −2.94 to −5.83 MV/cm for the negative field direction at room temperature and from +3.16 to +5.98 for the positive field direction at room temperature, (2) a positive remnant polarization at room temperature of about 120.5 μC/cm2 and a negative remnant polarization at room temperature of about −128.0 μC/cm²; (3) read cycling of about 10⁶ cycles at room temperature and at about 500° C.; (4) a retention time of at least 6 hours at room temperature and at about 500° C.; (5) a write endurance of about 6000 cycles at room temperature; and (6) a write endurance of about 1400 cycles at 500° C.

9. The component of claim 1, wherein the ferroelectric portion defines a height in the range of 10 to about 100 nm.

10. The component of claim 1, wherein the component is in electronic communication with a processor, the component optionally being wirebonded to the processor.

11. A method, comprising operating a component according to claim 1.

12. A method, comprising applying a voltage to a component according to claim 1 so as to convert the component between a first persistent electronic polarization and conduction state and a second persistent electronic polarization and conduction state.

13. A ferroelectric capacitor, comprising:
a first electrode comprising a first metal;
a ferroelectric portion,
the ferroelectric portion comprising AlₓSc₍₁₋ₓ₎N;
a second electrode comprising a second metal; and
a silicon carbide portion;
the ferroelectric portion contacting the first electrode and the silicon carbide portion,
the second electrode contacting the silicon carbide portion.

14. The capacitor of claim 13, wherein the first electrode comprises any one or more of Pt, Pd, Mo, Ti, Ni, W, Ta, and Au.

15. The capacitor of claim 13, wherein the second electrode comprises any one or more of Pt, Pd, Mo, Ti, Al, Ni, W, Ta, and Au.

16. The capacitor of claim 13, wherein x=0.6 to 0.8.

17. A method, comprising applying a voltage to a capacitor according to claim 13 so as to convert the capacitor between a first persistent electronic polarization and conduction state and a second electronic polarization and conduction persistent state.

18. A ferroelectric component, comprising:
a ferroelectric portion,
the ferroelectric portion comprising AlₓSc₍₁₋ₓ₎N;
a first electrode comprising a first metal,
the first electrode surmounting at least a portion of the ferroelectric portion; and
a second electrode comprising a second metal.

19. The component of claim 18, further comprising a silicon carbide support, the ferroelectric portion surmounting at least a portion of the silicon carbide support and the second electrode surmounting at least a portion of the silicon carbide support.

20. The component of claim 18, wherein x is from about 0.6 to about 0.8.
